(19) United States
(12) Patent Application Publication
(10) Pub. No.: US 2026/0231628 A1
(43) Pub. Date: Aug. 6, 2026

(54) DISPLAY DEVICE, METHOD OF MANUFACTURING THE SAME, AND ELECTRONIC DEVICE INCLUDING THE SAME

(71) Applicant: Samsung Display Co., Ltd., Yongin-si (KR)

(72) Inventors: DAEHO LEE, Yongin-si (KR); SOONKYEONG KWON, Yongin-si (KR); HYUN-SUK PARK, Yongin-si (KR); SUJI HAN, Yongin-si (KR)

(21) Appl. No.: 19/427,491

(22) Filed: Dec. 19, 2025

(30) Foreign Application Priority Data
Feb. 3, 2025 (KR) 10-2025-0012873

(51) Int. Cl. H10K 59/123; H10H 29/01; H10H 29/37; H10H 29/39; H10H 29/49; H10H 29/85; H10H 29/855; H10K 59/12; H10K 59/122; H10K 59/131; H10K 59/38; H10K 59/80; H10K 102/00

(52) U.S. Cl. CPC H10K 59/123; H10H 29/012; H10H 29/37; H10H 29/39; H10H 29/49; H10H 29/8517; H10H 29/855; H10K 59/1201; H10K 59/122; H10K 59/131; H10K 59/38; H10K 59/879; H10K 2102/351

(57) ABSTRACT

A display device includes a first lower electrode provided on a first transistor and electrically connected to the first transistor; a first conductive pattern provided between the first transistor and the first lower electrode, electrically connecting the first transistor and the first lower electrode, and having a first thickness; a second lower electrode provided on a second transistor different from the first transistor, electrically connected to the second transistor, and being adjacent to the first lower electrode; and a second conductive pattern provided between the second transistor and the second lower electrode, electrically connecting the second transistor and the second lower electrode, and having a second thickness different from the first thickness.

### CROSS-REFERENCE TO RELATED APPLICATION

The present application claims priority to and the benefit of Korean Patent Application No. 10-2025-0012873, filed on Feb. 3, 2025, in the Korean Intellectual Property Office, the entire disclosure of which is incorporated herein by reference.

### BACKGROUND

### 1. Field

One or more aspects of embodiments of the present disclosure relate to a display device, a method of manufacturing the display device, and an electronic device including the display device.

### 2. Description of the Related Art

A display device includes sub-pixels, each of which includes a lower electrode, an upper electrode, and a light-emitting layer provided between the lower electrode and the upper electrode. In order to improve the power efficiency of the light-emitting element, functional layers (e.g., a hole transport layer, an electron transport layer, an auxiliary layer, and/or the like) may be further provided on and under the light-emitting layer. Here, it may be necessary or useful to adjust an optimal or suitable resonance thickness (e.g., to provide constructive interference) in response to the color of light emitted from each of the sub-pixels.

As an option for controlling a resonance thickness, a display device having a lower electrode with an inorganic layer inserted therein has been suggested. However, in this case, a problem of the lower electrode being damaged may occur during a process of forming the inorganic layer.

Additionally, a display device having a lower electrode with a metal layer inserted therein has been suggested. In this case, a problem such as a decrease in hole injection capability due to the metal layer and an occurrence of work function deviation, and/or the like may occur.

### SUMMARY

One or more aspects of embodiments of the present disclosure is to provide a display device.

One or more aspects of embodiments of the present disclosure is to provide a method of manufacturing the display device.

One or more aspects of embodiments of the present disclosure is to provide an electronic device including the display device.

However, embodiments of the present disclosure are not limited to the above and may be variously modified and extended without departing from the spirit and scope of the present disclosure.

According to one or more embodiments of the present disclosure, a display device may include a first lower electrode provided on a first transistor and electrically connected to the first transistor, a first conductive pattern provided between the first transistor and the first lower electrode, electrically connecting the first transistor and the first lower electrode, and having a first thickness, a second lower electrode provided on a second transistor different from the first transistor, electrically connected to the second transistor, and being adjacent to the first lower electrode, and a second conductive pattern provided between the second transistor and the second lower electrode, electrically connecting the second transistor and the second lower electrode, and having a second thickness different from the first thickness.

In some embodiments, the first conductive pattern may include a different material from the first lower electrode.

In some embodiments, the first conductive pattern may include a metal oxide.

In some embodiments, the second conductive pattern may include the same material as the first conductive pattern.

In some embodiments, a first height of the first lower electrode may be different from a second height of the second lower electrode.

In some embodiments, a difference between the first height and the second height may be equal to a difference between the first thickness and the second thickness.

In some embodiments, the display device may further include a via layer provided between the first transistor and the first lower electrode and covering a first side surface of the first conductive pattern and a second side surface of the second conductive pattern.

In some embodiments, a portion of an upper surface of the via layer may coincide (e.g., may align) with an upper surface of the first conductive pattern and another portion of the upper surface of the via layer may coincide (e.g., may align) with an upper surface of the second conductive pattern.

In some embodiments, the upper surface of the first conductive pattern may not coincide with the upper surface of the second conductive pattern.

In some embodiments, a lower surface of the via layer, a lower surface of the first conductive pattern, and a lower surface of the second conductive pattern may coincide (e.g., may align) with each other.

In some embodiments, a thickness of the via layer covering the first side surface of the first conductive pattern may be different from a thickness of the via layer covering the second side surface of the second conductive pattern.

In some embodiments, the via layer may include an organic material.

In some embodiments, the display device may further include a pixel defining layer provided on the first lower electrode and the second lower electrode and overlapping with the first conductive pattern and the second conductive pattern.

In some embodiments, the pixel defining layer may expose a portion of the first lower electrode to define a first opening and a portion of the second lower electrode to define a second opening.

In some embodiments, the first conductive pattern may not overlap with the first opening.

In some embodiments, the second conductive pattern may not overlap with the second opening.

In some embodiments, the pixel defining layer may cover end portions of the first lower electrode and end portions of the second lower electrode.

In some embodiments, the first conductive pattern may overlap with one of the end portions of the first lower electrode.

In some embodiments, the second conductive pattern may overlap with one of the end portions of the second lower electrode.

In some embodiments, the display device may further include an intermediate layer provided on the first lower electrode and being in contact with the first lower electrode and an upper electrode provided on the intermediate layer.

In some embodiments, the first conductive pattern may be in contact with the first lower electrode.

In some embodiments, the intermediate layer may be further in contact with the second lower electrode.

In some embodiments, a first distance from the first lower electrode to the upper electrode may be different from a second distance from the second lower electrode to the upper electrode.

In some embodiments, a difference between the first distance and the second distance may be equal to a difference between the first thickness and the second thickness.

In some embodiments, the display device may further include a first color filter provided on the first lower electrode, a second color filter provided on the second lower electrode, and a micro lens array provided on the first and second color filters.

According to one or more embodiments of the present disclosure, a display device includes a first lower electrode provided on a first transistor and electrically connected to the first transistor, a first conductive pattern provided between the first transistor and the first lower electrode and electrically connecting the first transistor and the first lower electrode, and a via layer provided between the first transistor and the first lower electrode, covering a first side surface of the first conductive pattern, and having an upper surface a portion of which coincides with (e.g., is aligned with) an upper surface of the first conductive pattern.

In some embodiments, the display device may further include a second lower electrode provided on a second transistor different from the first transistor, electrically connected to the second transistor, and being adjacent to the first lower electrode and a second conductive pattern provided between the second transistor and the second lower electrode, electrically connecting the second transistor and the second lower electrode, and having a thickness different from a thickness of the first lower electrode.

In some embodiments, the via layer further may cover a second side surface of the second conductive pattern.

In some embodiments, another portion of the upper surface of the via layer may coincide with (e.g., be aligned with) an upper surface of the second conductive pattern.

In some embodiments, the upper surface of the first conductive pattern may not coincide with (e.g., may not be aligned with) the upper surface of the second conductive pattern.

In some embodiments, a lower surface of the via layer, a lower surface of the first conductive pattern, and a lower surface of the second conductive pattern may coincide with (e.g., may be aligned with) each other.

In some embodiments, a thickness of the via layer covering the first side surface may be different from a thickness of the via layer covering the second side surface.

In some embodiments, the via layer may include an organic material.

According to one or more embodiments of the present disclosure, a method of manufacturing a display device includes forming a first conductive pattern on a substrate, the first conductive pattern being electrically connected to a first transistor, forming a second preliminary conductive pattern on the substrate, the second preliminary conductive pattern being connected to a second transistor different from the first transistor, forming a first preliminary via layer covering the first conductive pattern and the second preliminary conductive pattern, forming a first via layer that exposes an upper surface of the first conductive pattern by removing a portion of the first preliminary via layer, forming a second preliminary via layer on the first via layer, and forming a second via layer and a second conductive pattern by removing a portion of the second preliminary via layer and a portion of the second preliminary conductive pattern.

In some embodiments, the method may further include forming a first lower electrode on the first via layer, the first lower electrode being in contact with the first conductive pattern and forming a second lower electrode on the second via layer, the second lower electrode being in contact with the second conductive pattern.

In some embodiments, the second preliminary via layer may further cover the first lower electrode.

In some embodiments, a thickness of the first conductive pattern may be equal to a thickness of the second preliminary conductive pattern.

In some embodiments, the thickness of the first conductive pattern may be different from a thickness of the second conductive pattern.

In some embodiments, the first via layer may be formed through a first planarization process.

In some embodiments, the second via layer may be formed through a second planarization process.

In some embodiments, the first planarization process and the second planarization process may be chemical mechanical polishing (CMP) processes.

In some embodiments, the method may further include forming a preliminary conductive pattern on the substrate.

In some embodiments, the first conductive pattern and the second preliminary conductive pattern may be formed together.

In some embodiments, the first conductive pattern and the second preliminary conductive pattern may be formed by patterning the preliminary conductive pattern.

In some embodiments, a thickness of the preliminary conductive pattern may be equal to a thickness of the first conductive pattern.

According to one or more embodiments of the present disclosure, an electronic device may include a display device configured to display an image and a power module configured to supply power to the display device. In one or more embodiments, the display device may include a first lower electrode provided on a first transistor and electrically connected to the first transistor, a first conductive pattern provided between the first transistor and the first lower electrode, electrically connecting the first transistor and the first lower electrode, and having a first thickness, a second lower electrode provided on a second transistor different from the first transistor, electrically connected to the second transistor, and being adjacent to the first lower electrode, and a second conductive pattern provided between the second transistor and the second lower electrode, electrically connecting the second transistor and the second lower electrode, and having a second thickness different from the first thickness.

For example, a display device according to one or more embodiments may include first to third conductive patterns. The first conductive pattern may electrically connect a first transistor and a first lower electrode, the second conductive pattern may electrically connect a second transistor and a second lower electrode, and the third conductive pattern may electrically connect a third transistor and a third lower electrode.

In some embodiments, a thickness of a via layer covering the first to third conductive patterns may not be constant. For example, the thickness of the via layer may vary from region to region. For example, the thickness of the via layer covering the first conductive pattern, the thickness of the via layer covering the second conductive pattern, and the thickness of the via layer covering the third conductive pattern may be different from each other.

As the thickness of the via layer is not constant, heights of upper surfaces of the first to third lower electrodes may be different from each other. As the heights of the upper surfaces of the first to third lower electrodes are different from each other, distances from the first to third lower electrodes to an upper electrode may be different from each other.

In this case, the distances may be set in consideration of a resonance order of light emitted from the first to third sub-pixels. Accordingly, a display quality of the display device may be improved.

However, effects of the present disclosure are not limited to the above effects and may be variously suitably extended and modified without departing from the spirit and scope of the present disclosure.

### BRIEF DESCRIPTION OF THE DRAWINGS

Illustrative, non-limiting embodiments will be more clearly understood from the following detailed description in conjunction with the accompanying drawings, in which:

FIG. 1 is a plan view illustrating a display device according to one or more embodiments.

FIG. 2 is a cross-sectional view illustrating the display device of FIG. 1.

FIG. 3 is a cross-sectional view illustrating an example of an intermediate layer included in the display device of FIG. 2.

FIG. 4 is a cross-sectional view illustrating another example of an intermediate layer included in the display device of FIG. 2.

FIG. 5 is a cross-sectional view illustrating still another example of an intermediate layer included in the display device of FIG. 2.

FIG. 6 is a cross-sectional view illustrating a transistor layer included in the display device of FIG. 2.

FIGS. 7-21 are each a cross-sectional views illustrating one or more acts of a method of manufacturing the display device of FIG. 2.

FIG. 22 is a block diagram illustrating an electronic device according to one or more embodiments.

### DETAILED DESCRIPTION

Hereinafter, embodiments of the present disclosure will be described in more detail with reference to the attached drawings. Identical components in the drawings will be designated by the same reference numerals, and redundant descriptions of the substantially identical components will not be provided.

It will be understood that, although the terms first, second, etc. may be used herein to describe various elements, these elements should not be limited by these terms. These terms are only used to distinguish one element from another element. Thus, a first element could be termed a second element without departing from the teachings of the present invention. Similarly, a second element could be termed a first element.

As used herein, the singular forms “a,” “an,” and “the” are intended to include the plural forms as well, unless the context clearly indicates otherwise.

It will be further understood that the terms “includes,” “including,” “comprises,” and/or “comprising,” when used in this specification, specify the presence of stated features, steps, operations, elements, and/or components, but do not preclude the presence or addition of one or more other features, steps, operations, elements, components, and/or groups thereof. Additionally, the terms “comprise(s)/comprising,” “include(s)/including,” “have/has/having” or similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof.

As used herein, the terms “use,” “using,” and “used” may be considered synonymous with the terms “utilize,” “utilizing,” and “utilized,” respectively.

As used herein, expressions such as “at least one of”, “one of”, and “selected from”, when preceding a list of elements, modify the entire list of elements and do not modify the individual elements of the list. For example, “at least one selected from among a, b and c”, “at least one of a, b or c”, and “at least one of a, b and/or c” may indicate only a, only b, only c, both (e.g., simultaneously) a and b, both (e.g., simultaneously) a and c, both (e.g., simultaneously) b and c, all of a, b, and c, or variations thereof.

As used herein, the term “and/or” includes any and all combinations of one or more of the associated listed items.

Further, the use of “may” when describing embodiments of the present disclosure refers to “one or more embodiments of the present disclosure”.

It will be understood that when an element is referred to as being “on,” “connected to,” or “coupled to” another element, it may be directly on, connected, or coupled to the other element or one or more intervening elements may also be present. When an element is referred to as being “directly on,” “directly connected to,” or “directly coupled to” another element, there are no intervening elements present.

Spatially relative terms, such as “beneath,” “below,” “lower,” “above,” “upper,” “bottom,” “top” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein should be interpreted accordingly.

As used herein, the terms “substantially”, “about”, and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

The electronic device and/or any other relevant devices or components according to embodiments of the present disclosure described herein may be implemented utilizing any suitable hardware, firmware (e.g. an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

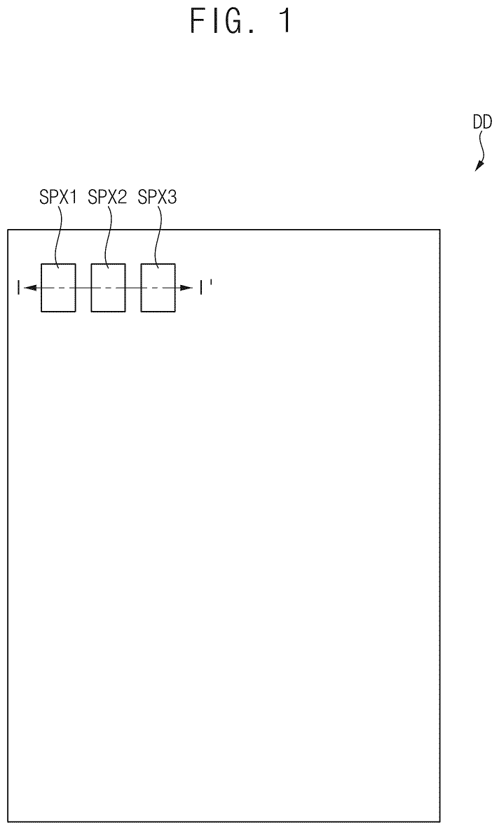

FIG. 1 is a plan view illustrating a display device according to one or more embodiments.

Referring to FIG. 1, the display device DD may include at least one sub-pixel. For example, the display device DD may include a first sub-pixel SPX1, a second sub-pixel SPX2, and a third sub-pixel SPX3.

In one or more embodiments, each of the first to third sub-pixels SPX1, SPX2, and SPX3 may be to emit light having a set or predetermined color. For example, the first sub-pixel SPX1 may be to emit light having a red color, the second sub-pixel SPX2 may be to emit light having a green color, and the third sub-pixel SPX3 may be to emit light having a blue color.

In one or more embodiments, the first to third sub-pixels SPX1, SPX2, and SPX3 may constitute one pixel. The display device DD may display an image using a plurality of pixels. However, the present disclosure is not limited thereto. For example, the pixel may further include a fourth sub-pixel that is to emit light having a green or white color.

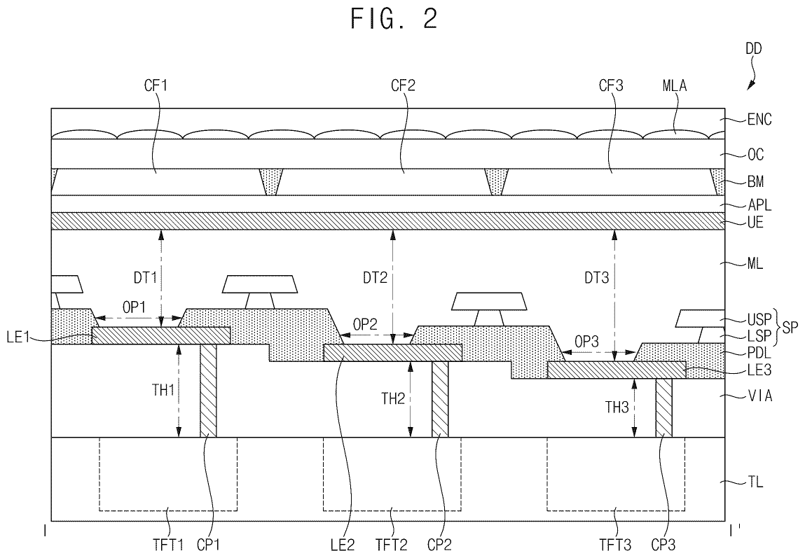

FIG. 2 is a cross-sectional view illustrating the display device of FIG. 1. For example, FIG. 2 is a cross-sectional view taken along the line II′ of FIG. 1.

Referring to FIG. 2, the display device DD may include a transistor layer TL, a first conductive pattern CP1, a second conductive pattern CP2, a third conductive pattern CP3, a via layer VIA, a first lower electrode LE1, a second lower electrode LE2, a third lower electrode LE3, a pixel defining layer PDL, a separation layer SP, an intermediate layer ML, an upper electrode UE, a protective layer APL, a black matrix BM, a first color filter CF1, a second color filter CF2, a third color filter CF3, a planarization layer OC, a micro lens array MLA, and an encapsulation layer ENC.

At least one transistor may be formed in the transistor layer TL. For example, a first transistor TFT1, a second transistor TFT2, and a third transistor TFT3 may be formed in the transistor layer TL. The first sub-pixel SPX1 may correspond to the first transistor TFT1, the first lower electrode LE1, and the first color filter CF1. The second sub-pixel SPX2 may correspond to the second transistor TFT2, the second lower electrode LE2, and the second color filter CF2. The third sub-pixel SPX3 may correspond to the third transistor TFT3, the third lower electrode LE3, and the third color filter CF3.

The separation layer SP may include a lower separation layer LSP and an upper separation layer USP.

In one or more embodiments, the display device DD may further include a quantum dot QD, a phase delay layer, a polarizing layer, and/or the like.

The first conductive pattern CP1 may be provided on the transistor layer TL. In one or more embodiments, the first conductive pattern CP1 may be electrically connected to the first transistor TFT1.

In one or more embodiments, the first conductive pattern CP1 may include a conductive material such as a metal, an alloy, a metal oxide, and/or the like. For example, the first conductive pattern CP1 may include silver (Ag), an alloy containing silver, molybdenum (Mo), an alloy containing molybdenum, aluminum (Al), an alloy containing aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), indium zinc oxide (IZO), and/or the like. These materials may be used alone or in combination with each other. In one or more embodiments, the first conductive pattern CP1 may be formed to have a single-layer structure or a multi-layer structure.

The second conductive pattern CP2 may be provided on the transistor layer TL. In one or more embodiments, the second conductive pattern CP2 may be electrically connected to the second transistor TFT2.

In one or more embodiments, the second conductive pattern CP2 may include a conductive material such as a metal, an alloy, and/or a metal oxide. For example, the second conductive pattern CP2 may include silver (Ag), an alloy containing silver, molybdenum (Mo), an alloy containing molybdenum, aluminum (Al), an alloy containing aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), indium zinc oxide (IZO), and/or the like. These materials may be used alone or in combination with each other. In one or more embodiments, the second conductive pattern CP2 may be formed to have a single-layer structure or a multi-layer structure.

The third conductive pattern CP3 may be provided on the transistor layer TL. In one or more embodiments, the third conductive pattern CP3 may be electrically connected to the third transistor TFT3.

In one or more embodiments, the third conductive pattern CP3 may include a conductive material such as a metal, an alloy, and/or a metal oxide. For example, the third conductive pattern CP3 may include silver (Ag), an alloy containing silver, molybdenum (Mo), an alloy containing molybdenum, aluminum (Al), an alloy containing aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), indium zinc oxide (IZO), and/or the like. These materials may be used alone or in combination with each other. In one or more embodiments, the third conductive pattern CP3 may be formed to have a single-layer structure or a multi-layer structure.

In one or more embodiments, the first conductive pattern CP1, the second conductive pattern CP2, and the third conductive pattern CP3 may include the same material. For example, the first conductive pattern CP1, the second conductive pattern CP2, and the third conductive pattern CP3 may include a metal oxide (e.g., ITO, IZO, and/or the like).

The first conductive pattern CP1 may have a first thickness TH1, the second conductive pattern CP2 may have a second thickness TH2, and the third conductive pattern CP3 may have a third thickness TH3. In one or more embodiments, the first thickness TH1, the second thickness TH2, and the third thickness TH3 may be different from each other. For example, the first thickness TH1 may be greater (or thicker) than the second thickness TH2, and the second thickness TH2 may be greater than the third thickness TH3.

However, the present disclosure is not limited thereto. For example, the first to third thicknesses TH1, TH2, and TH3 may be appropriately or suitably set in consideration of a resonance order of light emitted from the first to third sub-pixels SPX1, SPX2, and SPX3.

The via layer VIA may be provided on the transistor layer TL. In one or more embodiments, the via layer VIA may cover a first side surface of the first conductive pattern CP1, a second side surface of the second conductive pattern CP2, and a third side surface of the third conductive pattern CP3. For example, a portion of via layer VIA may cover a first side surface of the first conductive pattern CP1, another portion of the via layer VIA may cover a second side surface of the second conductive pattern CP2, and yet another portion of the via layer VIA may cover a third side surface of the third conductive pattern CP3.

In one or more embodiments, the via layer VIA may include an organic material. For example, the via layer VIA may include a photoresist, a polyacrylic resin, a polyimide resin, an acrylic resin, and/or the like. These materials may be used alone or in combination with each other.

In some embodiments, the via layer VIA may include an inorganic material. For example, the via layer VIA may include silicon oxide, silicon nitride, silicon oxynitride, and/or the like. These materials may be used alone or in combination with each other.

In some embodiments, the via layer VIA may include an organic material and an inorganic material. For example, the via layer VIA may include an organic layer and an inorganic layer provided on the organic layer.

In one or more embodiments, a thickness of the via layer VIA adjacent to the first conductive pattern CP1 may be substantially the same as the first thickness TH1. For example, the thickness of the via layer VIA covering the first side surface of the first conductive pattern CP1 may be substantially equal to the first thickness TH1.

In one or more embodiments, the thickness of the via layer VIA adjacent to the second conductive pattern CP2 may be substantially the same as the second thickness TH2. For example, the thickness of the via layer VIA covering the second side surface of the second conductive pattern CP2 may be substantially the same as the second thickness TH2.

Furthermore, the thickness of the via layer VIA adjacent to the third conductive pattern CP3 may be substantially the same as the third thickness TH3. For example, the thickness of the via layer VIA covering the third side surface of the third conductive pattern CP3 may be substantially the same as the third thickness TH3.

In one or more embodiments, the thickness of the via layer VIA may not be constant. For example, the via layer VIA may have different thicknesses corresponding to the first to third sub-pixels SPX1, SPX2, and SPX3.

For example, the thickness of the via layer VIA covering the first side surface of the first conductive pattern CP1, the thickness of the via layer VIA covering the second side surface of the second conductive pattern CP2, and the thickness of the via layer VIA covering the third side surface of the third conductive pattern CP3 may be different from each other. For example, the thickness of the via layer VIA covering the first side surface of the first conductive pattern CP1 may be greater than the thickness of the via layer VIA covering the second side surface of the second conductive pattern CP2, and the thickness of the via layer VIA covering the second side surface of the second conductive pattern CP2 may be greater than the thickness of the via layer VIA covering the third side surface of the third conductive pattern CP3.

In one or more embodiments, a lower surface of the via layer VIA, a lower surface of the first conductive pattern CP1, a lower surface of the second conductive pattern CP2, and a lower surface of the third conductive pattern CP3 may coincide (e.g., may be coplanar and/or aligned) with each other. In one or more embodiments, a first portion of an upper surface of the via layer VIA may coincide (e.g., may be coplanar and/or aligned) with an upper surface of the first conductive pattern CP1, a second portion of the upper surface of the via layer VIA may coincide (e.g., may be coplanar and/or aligned) with an upper surface of the second conductive pattern CP2, and a third portion of the upper surface of the via layer VIA may coincide (e.g., may be coplanar and/or aligned) with an upper surface of the third conductive pattern CP3. Here, the upper surface of the first conductive pattern CP1, the upper surface of the second conductive pattern CP2, and the upper surface of the third conductive pattern CP3 may not coincide (e.g., may not align) with each other.

The first lower electrode LE1 may be provided on the via layer VIA. In one or more embodiments, the first lower electrode LE1 may be provided on the first conductive pattern CP1 and may be in contact with the first conductive pattern CP1. Accordingly, the first lower electrode LE1 may be electrically connected to the first transistor TFT1 through the first conductive pattern CP1.

The second lower electrode LE2 may be provided on the via layer VIA and may be adjacent to the first lower electrode LE1. In one or more embodiments, the second lower electrode LE2 may be provided on the second conductive pattern CP2 and may be in contact with the second conductive pattern CP2. Accordingly, the second lower electrode LE2 may be electrically connected to the second transistor TFT2 through the second conductive pattern CP2.

The third lower electrode LE3 may be provided on the via layer VIA and may be adjacent to the second lower electrode LE2. In one or more embodiments, the third lower electrode LE3 may be provided on the third conductive pattern CP3 and may be in contact with the third conductive pattern CP3. Accordingly, the third lower electrode LE3 may be electrically connected to the third transistor TFT3 through the third conductive pattern CP3.

In one or more embodiments, the first to third lower electrodes LE1, LE2, and LE3 may include a conductive material such as a metal, an alloy, and/or a metal oxide. For example, the first to third lower electrodes LE1, LE2, and LE3 may include silver (Ag), an alloy containing silver, molybdenum (Mo), an alloy containing molybdenum, aluminum (Al), an alloy containing aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), indium zinc oxide (IZO), and/or the like. These materials may be used alone or in combination with each other. In one or more embodiments, the first to third lower electrodes LE1, LE2, and LE3 may each independently be formed to have a single-layer structure or a multi-layer structure.

In one or more embodiments, the first to third lower electrodes LE1, LE2, and LE3 may include the same material. For example, each of the first to third lower electrodes LE1, LE2, and LE3 may have an ITO/Ag/ITO structure.

In one or more embodiments, the first to third conductive patterns CP1, CP2, and CP3 may include a different material from the material included in the first to third lower electrodes LE1, LE2, and LE3.

In one or more embodiments, a first height of the first lower electrode LE1, a second height of the second lower electrode LE2, and a third height of the third lower electrode LE3 may be different from each other. For example, the first height may be greater than the second height, and the second height may be greater than the third height. In this case, a height of the lower electrode LE may be defined as a height of an upper surface of the lower electrode LE, for example, as a distance between the bottom surface of the via layer VIA and the upper surface of the lower electrode.

In one or more embodiments, a difference between the first height of the first lower electrode LE1 and the second height of the second lower electrode LE2 may be substantially equal to a difference between the first thickness TH1 and the second thickness TH2. Additionally, a difference between the second height of the second lower electrode LE2 and the third height of the third lower electrode LE3 may be substantially equal to a difference between the second thickness TH2 and the third thickness TH3.

In one or more embodiments, a thickness of the first lower electrode LE1, a thickness of the second lower electrode LE2, and a thickness of the third lower electrode LE3 may be the same as each other. Here, the thickness of the lower electrode may refer to a distance between the lower surface and the upper surface of the corresponding lower electrode.

The pixel defining layer PDL may be provided on the via layer VIA. In one or more embodiments, the pixel defining layer PDL may include an organic material. For example, the pixel defining layer PDL may include a photoresist, a polyacrylic resin, a polyimide resin, an acrylic resin, and/or the like. These materials may be used alone or in combination with each other. In one or more embodiments, the pixel defining layer PDL may be formed to have a single-layer structure or a multi-layer structure.

In one or more embodiments, the pixel defining layer PDL may cover end portions of the first lower electrode LE1, end portions of the second lower electrode LE2, and end portions of the third lower electrode LE3. In one or more embodiments, the pixel defining layer PDL may expose a portion of the first lower electrode LE1 (e.g., a first opening OP1 is defined), a portion of the second lower electrode LE2 (e.g., a second opening OP2 is defined), and a portion of the third lower electrode LE3 (e.g., a third opening OP3 is defined).

In one or more embodiments, the first to third conductive patterns CP1, CP2, and CP3 may overlap with the pixel defining layer PDL. For example, the first conductive pattern CP1 may overlap with the pixel defining layer PDL covering an end portion of the first lower electrode LE1, the second conductive pattern CP2 may overlap with the pixel defining layer PDL covering an end portion of the second lower electrode LE2, and the third conductive pattern CP3 may overlap with the pixel defining layer PDL covering an end portion of the third lower electrode LE3.

In one or more embodiments, the first to third conductive patterns CP1, CP2, and CP3 may not overlap with the first to third openings OP1, OP2, and OP3. For example, the first conductive pattern CP1 may not overlap with the first opening OP1, the second conductive pattern CP2 may not overlap with the second opening OP2, and the third conductive pattern CP3 may not overlap with the third opening OP3.

The separation layer SP may be provided on the pixel defining layer PDL. In one or more embodiments, the separation layer SP may include a lower separation layer LSP and an upper separation layer USP. The lower separation layer LSP may include a metal, an alloy, a metal oxide, and/or the like and may be provided on the pixel defining layer PDL. The upper separation layer USP may include an inorganic material and may be provided on the lower separation layer LSP.

The intermediate layer ML may be provided on the first to third lower electrodes LE1, LE2, and LE3. The intermediate layer ML may include a light-emitting layer, a hole transport layer, an electron transport layer, and/or the like. The light-emitting layer may emit light, the hole transport layer may transport holes to the light-emitting layer, and the electron transport layer may transport electrons to the light-emitting layer.

In one or more embodiments, the intermediate layer ML may be in contact with the first to third lower electrodes LE1, LE2, and LE3. For example, an additional layer such as an inorganic layer, an organic layer, a metal layer, and/or the like may not be inserted between the first lower electrode LE1 (and/or the second lower electrode LE2 and/or the third lower electrode LE3) and the intermediate layer ML.

In one or more embodiments, the intermediate layer ML may be formed as a common layer. For example, the intermediate layer ML may be formed continuously across the first to third lower electrodes LE1, LE2, and LE3.

In some embodiments, the intermediate layer ML may be formed discontinuously on each of the first to third lower electrodes LE1, LE2, and LE3. For example, the intermediate layer ML may include a first intermediate layer formed on the first lower electrode LE1 and including a red color light-emitting layer, a second intermediate layer formed on the second lower electrode LE2 and including a green color light-emitting layer, and a third intermediate layer formed on the third lower electrode LE3 and including a blue color light-emitting layer.

The upper electrode UE may be provided on the intermediate layer ML. In one or more embodiments, the upper electrode UE may be in contact with the intermediate layer ML.

In one or more embodiments, the upper electrode UE may include a conductive material such as a metal, an alloy, and/or a metal oxide. For example, the upper electrode UE may include silver (Ag), an alloy containing silver, molybdenum (Mo), an alloy containing molybdenum, aluminum (Al), an alloy containing aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), indium zinc oxide (IZO), and/or the like. These materials may be used alone or in combination with each other. In one or more embodiments, the upper electrode UE may be formed to have a single-layer structure or a multi-layer structure.

In one or more embodiments, a first distance DT1 from the first lower electrode LE1 (e.g., from the upper surface of the first lower electrode LE1) to the upper electrode UE, a second distance DT2 from the second lower electrode LE2 (e.g., from the upper surface of the second lower electrode LE2) to the upper electrode UE, and a third distance DT3 from the third lower electrode LE3 (e.g., from the upper surface of the third lower electrode LE3) to the upper electrode UE may be different from each other. For example, the first distance DT1 may be smaller (or shorter) than the second distance DT2, and the second distance DT2 may be smaller than the third distance DT3.

However, the present disclosure is not limited thereto. For example, the first to third distances DT1, DT2, and DT3 may be appropriately or suitably set in consideration of the resonance order of the light emitted from the first to third sub-pixels SPX1, SPX2, and SPX3.

In one or more embodiments, a difference between the first distance DT1 and the second distance DT2 may be substantially equal to the difference between the first thickness TH1 and the second thickness TH2. Additionally, a difference between the second distance DT2 and the third distance DT3 may be substantially equal to the difference between the second thickness TH2 and the third thickness TH3.

The protective layer APL may be provided on the upper electrode UE. The protective layer APL may include an organic material and/or an inorganic material. In one or more embodiments, the protective layer APL may further include an adhesive material.

The black matrix BM may be provided on the protective layer APL. The black matrix BM may include a light-blocking material.

The first color filter CF1, the second color filter CF2, and the third color filter CF3 may be provided on the protective layer APL. In one or more embodiments, the first color filter CF1 may overlap with the first lower electrode LE1 and may be to transmit red color light. The second color filter CF2 may overlap with the second lower electrode LE2 and may be to transmit green color light. The third color filter CF3 may overlap with the third lower electrode LE3 and may be to transmit blue color light.

The planarization layer OC may be provided on the first to third color filters CF1, CF2, and CF3. The planarization layer OC may include an organic material and/or an inorganic material.

The micro lens array MLA may be arranged on the planarization layer OC. In one or more embodiments, the micro lens array MLA may include a plurality of micro lenses. The micro lens array MLA may create a virtual image from an image provided from the intermediate layer ML and the first to third color filters CF1, CF2, and CF3.

The encapsulation layer ENC may be provided on the micro lens array MLA. The encapsulation layer ENC may have a structure in which inorganic layers and organic layers are alternately arranged (or stacked) and may prevent or reduce the penetration of moisture and/or oxygen.

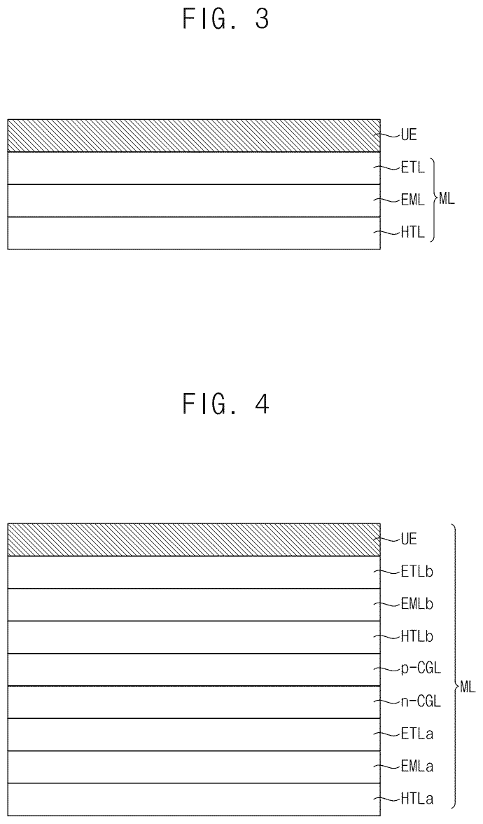

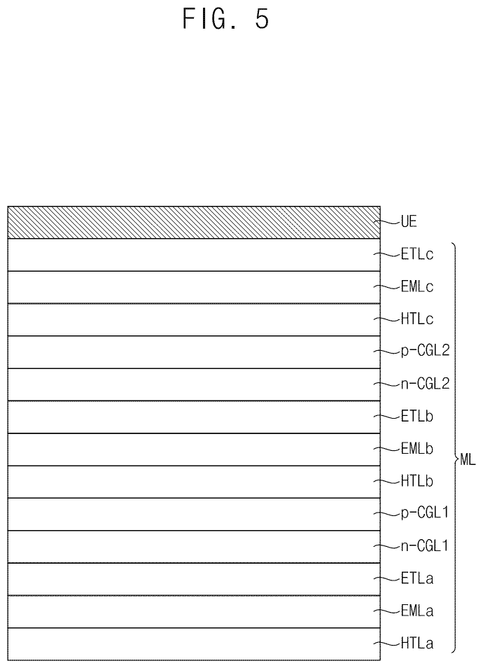

FIG. 3 is a cross-sectional view illustrating an example of an intermediate layer included in the display device of FIG. 2, FIG. 4 is a cross-sectional view illustrating another example of an intermediate layer included in the display device of FIG. 2, and FIG. 5 is a cross-sectional view illustrating still another example of an intermediate layer included in the display device of FIG. 2.

Referring to FIG. 3, the intermediate layer ML may include the hole transport layer HTL, the light-emitting layer EML, and the electron transport layer ETL.

The hole transport layer HTL may increase the mobility of holes toward the light-emitting layer EML. In one or more embodiments, the hole transport layer HTL may include a hole transport material. For example, the hole transport layer HTL may include at least one selected from among HATCN (1,4,5,8,9,11-hexaazatriphenylene-hexanitrile), CuPc (copper phthalocyanine), PEDOT (poly(3,4)-ethylenedioxythiophene), PANI (polyaniline), and NPD (N,N-dinaphthyl-N,N′-diphenylbenzidine).

The light-emitting layer EML may be provided on the hole transport layer HTL. The light-emitting layer EML may include a light-emitting material.

In one or more embodiments, the light-emitting layer EML may be to emit white color light. For example, the light-emitting layer EML may include light-emitting materials that may emit light of different colors, and the white color light may be emitted by combining the lights emitted from the light-emitting materials. The light-emitting material included in the light-emitting layer EML may be an organic light-emitting material, an inorganic light-emitting material, and/or a combination thereof.

However, the present disclosure is not limited thereto. For example, the light-emitting layer EML may be to emit blue color light.

The electron transport layer ETL may be provided on the light-emitting layer EML. The electron transport layer ETL may increase the mobility of electrons toward the light-emitting layer EML. In one or more embodiments, the electron transport layer ETL may include an electron transport material. For example, the electron transport layer ETL may include at least one selected from among LiQ (8-Hydroxyquinolinolato-lithium), Alq3 (tris(8-hydroxyquinolino)-aluminum), PBD (2-(4-biphenylyl)-5-(4-tert-butylpheny)-1,3,4oxadiazole), TAZ, and spiro-PBD.

Referring to FIG. 4, the intermediate layer ML may include a first hole transport layer HTLa, a first light-emitting layer EMLa, a first electron transport layer ETLa, an n-type charge generation layer n-CGL, a p-type charge generation layer p-CGL, a second hole transport layer HTLb, a second light-emitting layer EMLb, and a second electron transport layer ETLb.

The first hole transport layer HTLa may increase the mobility of holes toward the first light-emitting layer EMLa. In one or more embodiments, the first hole transport layer HTLa may include a hole transport material. Description of the material included in the first hole transport layer HTLa may be same as for the hole transport layer HTL described in connection with FIG. 3.

The first light-emitting layer EMLa may be provided on the first hole transport layer HTLa. The first light-emitting layer EMLa may include a light-emitting material. Description of the material included in the first light-emitting layer EMLa may be same as for the light-emitting layer EML described in connection with FIG. 3.

The first electron transport layer ETLa may be provided on the first light-emitting layer EMLa. The first electron transport layer ETLa may increase the mobility of electrons toward the first light-emitting layer EMLa. Description of the material included in the first electron transport layer ETLa may be same as for the electron transport layer ETL described in connection with FIG. 3.

The n-type charge generation layer n-CGL may be provided on the first electron transport layer ETLa, and the p-type charge generation layer p-CGL may be provided on the n-type charge generation layer n-CGL. The n-type charge generation layer n-CGL and the p-type charge generation layer p-CGL may control the charge balance between the first light-emitting layer EMLa and the second light-emitting layer EMLb. For example, the n-type charge generation layer n-CGL and the p-type charge generation layer p-CGL may include an electron transport material and/or a hole transport material containing an n-type dopant and/or a p-type dopant.

The second hole transport layer HTLb may be provided on the p-type charge generation layer p-CGL. The second hole transport layer HTLb may increase the mobility of holes toward the second light-emitting layer EMLb. In one or more embodiments, the second hole transport layer HTLb may include a hole transport material. Description of the material included in the second hole transport layer HTLb may be same as for the hole transport layer HTL described in connection with FIG. 3.

The second light-emitting layer EMLb may be provided on the second hole transport layer HTLb. The second light-emitting layer EMLb may include a light-emitting material. Description of the material included in the second light-emitting layer EMLb may be same as for the light-emitting layer EML described in connection with FIG. 3.

The first light-emitting layer EMLa and the second light-emitting layer EMLb may be to emit light of the same color or lights of different colors. Accordingly, the intermediate layer ML may be to emit the white color light. For example, the first light-emitting layer EMLa may be to emit the blue color light, and the second light-emitting layer EMLb may be to emit the green color light.

The second electron transport layer ETLb may be provided on the second light-emitting layer EMLb. The second electron transport layer ETLb may increase the mobility of electrons toward the second light-emitting layer EMLb. Description of the material included in the second electron transport layer ETLb may be same as for the electron transport layer ETL described in connection with FIG. 3.

Referring to FIG. 5, the intermediate layer ML may include a first hole transport layer HTLa, a first light-emitting layer EMLa, a first electron transport layer ETLa, a first n-type charge generation layer n-CGL1, a first p-type charge generation layer p-CGL1, a second hole transport layer HTLb, a second light-emitting layer EMLb, a second electron transport layer ETLb, a second n-type charge generation layer n-CGL2, a second p-type charge generation layer p-CGL2, a third hole transport layer HTLc, a third light-emitting layer EMLc, and a third electron transport layer ETLc.

The first hole transport layer HTLa may increase the mobility of holes toward the first light-emitting layer EMLa. In one or more embodiments, the first hole transport layer HTLa may include a hole transport material.

The first light-emitting layer EMLa may be provided on the first hole transport layer HTLa. The first light-emitting layer EMLa may include a light-emitting material.

The first electron transport layer ETLa may be provided on the first light-emitting layer EMLa. The first electron transport layer ETLa may increase the mobility of electrons toward the first light-emitting layer EMLa.

The first n-type charge generation layer n-CGL1 may be provided on the first electron transport layer ETLa, and the first p-type charge generation layer p-CGL1 may be provided on the first n-type charge generation layer n-CGL1. The first n-type charge generation layer n-CGL1 and the first p-type charge generation layer p-CGL1 may control the charge balance between the first light-emitting layer EMLa and the second light-emitting layer EMLb.

The second hole transport layer HTLb may be provided on the first p-type charge generation layer p-CGL1. The second hole transport layer HTLb may increase the mobility of holes toward the second light-emitting layer EMLb. In one or more embodiments, the second hole transport layer HTLb may include a hole transport material.

The second light-emitting layer EMLb may be provided on the second hole transport layer HTLb. The second light-emitting layer EMLb may include a light-emitting material.

The second electron transport layer ETLb may be provided on the second light-emitting layer EMLb. The second electron transport layer ETLb may increase the mobility of electrons toward the second light-emitting layer EMLb.

The second n-type charge generation layer n-CGL2 may be provided on the second electron transport layer ETLb, and the second p-type charge generation layer p-CGL2 may be provided on the second n-type charge generation layer n-CGL2. The second n-type charge generation layer n-CGL2 and the second p-type charge generation layer p-CGL2 may control the charge balance between the second light-emitting layer EMLb and the third light-emitting layer EMLc.

The third hole transport layer HTLc may be provided on the second p-type charge generation layer p-CGL2. The third hole transport layer HTLc may increase the mobility of holes toward the third light-emitting layer EMLc. In one or more embodiments, the third hole transport layer HTLc may include a hole transport material.

The third light-emitting layer EMLc may be provided on the third hole transport layer HTLc. The third light-emitting layer EMLc may include a light-emitting material.

The first light-emitting layer EMLa, the second light-emitting layer EMLb, and the third light-emitting layer EMLc may be to emit light of the same color or lights of different colors. Accordingly, the intermediate layer ML may be to emit the white color light. For example, the first light-emitting layer EMLa and the second light-emitting layer EMLb may be to emit the blue color light, and the third light-emitting layer EMLc may be to emit the green color light.

The third electron transport layer ETLc may be provided on the third light-emitting layer EMLc. The third electron transport layer ETLc may increase the mobility of electrons toward the third light-emitting layer EMLc.

Descriptions of materials for the first hole transport layer HTLa, the first light-emitting layer EMLa, the first electron transport layer ETLa, the first n-type charge generation layer n-CGL1, the first p-type charge generation layer p-CGL1, the second hole transport layer HTLb, the second light-emitting layer EMLb, and the second electron transport layer ETLb may be the same as described above. Descriptions of the materials for the second n-type charge generation layer n-CGL2, the second p-type charge generation layer p-CGL2, the third hole transport layer HTLc, the third light-emitting layer EMLc, and the third electron transport layer ETLc may be the same as described above in connection with the first n-type charge generation layer n-CGL1, the first p-type charge generation layer p-CGL1, the first hole transport layer HTLa, the first light-emitting layer EMLa, and the first electron transport layer ETLa, respectively.

In one or more embodiments, the intermediate layer ML described above with reference to FIGS. 3 to 5 may not include (e.g., may exclude) an auxiliary layer, which is a layer that reinforces the resonance of the light emitted from the light-emitting layer. For example, because the display device DD can reinforce the resonance of the light by utilizing respective thicknesses of the first to third conductive patterns CP1, CP2, and CP3, the auxiliary layer may not be formed in the intermediate layer ML. Accordingly, the process for implementing the intermediate layer ML as the common layer may be facilitated.

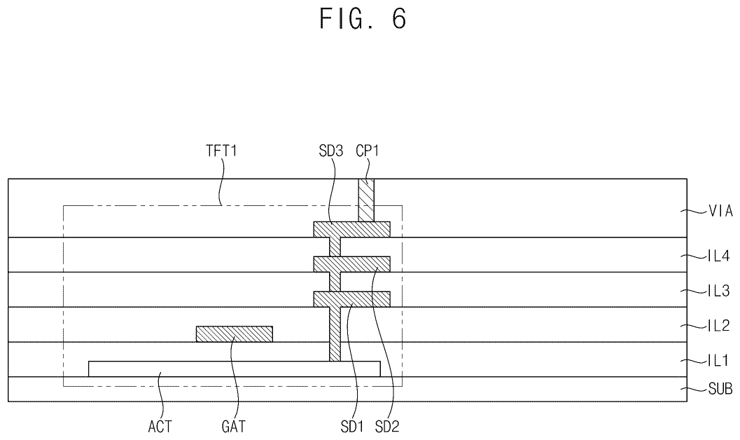

FIG. 6 is a cross-sectional view illustrating a transistor layer included in the display device of FIG. 2.

Referring to FIG. 6, the transistor layer TL may include a substrate SUB, an active pattern ACT, a first insulating layer IL1, a gate electrode GAT, a second insulating layer IL2, a first connection electrode SD1, a third insulating layer IL3, a second connection electrode SD2, a fourth insulating layer IL4, and a third connection electrode SD3.

The active pattern ACT, the gate electrode GAT, the first connection electrode SD1, the second connection electrode SD2, and the third connection electrode SD3 may constitute the first transistor TFT1. Each of the second transistor TFT2 and the third transistor TFT3 may have substantially the same structure as the first transistor TFT1.

In one or more embodiments, the substrate SUB may be formed of glass, quartz, plastic, and/or the like. Examples of materials that can be used as the plastic may include polyimide (PI), polyacrylate, polymethylmethacrylate (PMMA), polycarbonate (PC), polyethylenenaphthalate (PEN), polyvinylidene chloride, polyvinylidene difluoride (PVDF), polystyrene, ethylene vinylalcohol copolymer, polyethersulfone (PES), polyetherimide (PEI), polyphenylene sulfide (PPS), polyallylate, triacetyl cellulose (TAC), cellulose acetate propionate (CAP), and/or the like. These materials may be used alone or in combination with each other.

In some embodiments, the substrate SUB may be a silicon wafer substrate including silicon. In some embodiments, the substrate SUB may be a sapphire substrate including sapphire. However, the present disclosure is not limited thereto. For example, the substrate SUB may include one or more suitable materials other than silicon and sapphire.

The active pattern ACT may be provided on the substrate SUB. In one or more embodiments, the active pattern ACT may be formed of an oxide semiconductor material and/or a silicon semiconductor material.

Examples of the oxide semiconductor material that can be used for the active pattern ACT may include IGZO (InGaZnO), ITZO (InSnZnO), and/or the like. In one or more embodiments, the oxide semiconductor material may further include indium (In), gallium (Ga), tin (Sn), zirconium (Zr), vanadium (V), hafnium (Hf), cadmium (Cd), germanium (Ge), chromium (Cr), titanium (Ti), and/or zinc (Zn). These materials may be used alone or in combination with each other.

Examples of the silicon semiconductor material that can be used for the active pattern ACT may include amorphous silicon, polycrystalline silicon, and/or the like.

The first insulating layer IL1 may be provided on the substrate SUB and may cover the active pattern ACT. In one or more embodiments, the first insulating layer IL1 may be formed of an insulating material. Examples of the insulating material that can be used for the first insulating layer IL1 may include silicon oxide, silicon nitride, silicon oxynitride, and/or the like. These materials may be used alone or in combination with each other.

The gate electrode GAT may be provided on the first insulating layer IL1. In one or more embodiments, the gate electrode GAT may include a conductive material such as a metal, an alloy, and/or a metal oxide. For example, the gate electrode GAT may include silver (Ag), an alloy containing silver, molybdenum (Mo), an alloy containing molybdenum, aluminum (Al), an alloy containing aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), indium zinc oxide (IZO), and/or the like. These materials may be used alone or in combination with each other. In one or more embodiments, the gate electrode GAT may be formed to have a single-layer structure or a multi-layer structure.

The second insulating layer IL2 may be provided on the first insulating layer IL1 and may cover the gate electrode GAT. In one or more embodiments, the second insulating layer IL2 may be formed of an insulating material. Examples of the insulating material that can be used for the second insulating layer IL2 may include silicon oxide, silicon nitride, silicon oxynitride, and/or the like. These materials may be used alone or in combination with each other.

The first connection electrode SD1 may be provided on the second insulating layer IL2 and may be connected to the active pattern ACT. In one or more embodiments, the first connection electrode SD1 may include a conductive material such as a metal, an alloy, and/or a metal oxide. For example, the first connection electrode SD1 may have a Ti/Al/Ti structure.

The third insulating layer IL3 may be provided on the second insulating layer IL2 and may cover the first connection electrode SD1. In one or more embodiments, the third insulating layer IL3 may be formed of an insulating material. Examples of the insulating material that can be used for the third insulating layer IL3 may include an organic material and/or an inorganic material. These materials may be used alone or in combination with each other.

The second connection electrode SD2 may be provided on the third insulating layer IL3 and may be connected to the first connection electrode SD1. In one or more embodiments, the second connection electrode SD2 may include a conductive material such as a metal, an alloy, and/or a metal oxide. For example, the second connection electrode SD2 may have a Ti/Al/Ti structure.

The fourth insulating layer IL4 may be provided on the third insulating layer IL3 and may cover the second connection electrode SD2. In one or more embodiments, the fourth insulating layer IL4 may be formed of an insulating material. Examples of the insulating material that can be used for the fourth insulating layer IL4 may include an organic material and/or an inorganic material. These materials may be used alone or in combination with each other.

The third connection electrode SD3 may be provided on the fourth insulating layer IL4 and may be connected to the second connection electrode SD2. In one or more embodiments, the third connection electrode SD3 may be in contact with the first conductive pattern CP1. In one or more embodiments, the third connection electrode SD3 may include a conductive material such as a metal, an alloy, and/or a metal oxide. For example, the third connection electrode SD3 may have a Ti/Al/Ti structure.

The display device DD may include the first to third conductive patterns CP1, CP2, and CP3. The first to third conductive patterns CP1, CP2, and CP3 may electrically connect the first to third transistors TFT1, TFT2, and TFT3 and the first to third lower electrodes LE1, LE2, and LE3, respectively. For example, the first conductive pattern CP1 may electrically connect the first transistor TFT1 and the first lower electrode LE1, the second conductive pattern CP2 may electrically connect the second transistor TFT2 and the second lower electrode LE2, and the third conductive pattern CP3 may electrically connect the third transistor TFT3 and the third lower electrode LE3.

In one or more embodiments, the thickness of the via layer VIA covering the first to third conductive patterns CP1, CP2, and CP3 may not be constant. For example, the thickness of the via layer VIA may be different for each region. For example, the thickness of the via layer VIA covering the first conductive pattern CP1, the thickness of the via layer VIA covering the second conductive pattern CP2, and the thickness of the via layer VIA covering the third conductive pattern CP3 may be different from each other.

Because the thickness of the via layer VIA is not constant, the heights of the upper surfaces of the first to third lower electrodes LE1, LE2, and LE3 may be different from each other. Because the heights of the upper surfaces of the first to third lower electrodes LE1, LE2, and LE3 are different from each other, the distances from the first to third lower electrodes LE1, LE2, and LE3 to the upper electrode UE (e.g., the first to third distances DT1, DT2, and DT3) may be different from each other.

In this case, the first to third distances DT1, DT2, and DT3 may be set in consideration of the resonance order of the light emitted from the first to third sub-pixels SPX1, SPX2, and SPX3. Accordingly, a display quality of the display device DD may be improved.

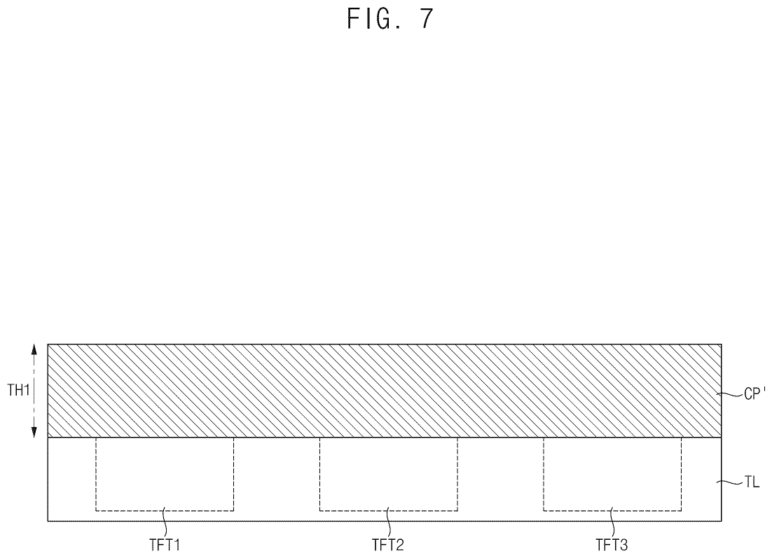

FIGS. 7 to 21 are cross-sectional views illustrating a method of manufacturing the display device of FIG. 2.

Referring to FIG. 7, a preliminary conductive pattern CP′ may be formed on the transistor layer TL. In one or more embodiments, the preliminary conductive pattern CP′ may include a conductive material such as a metal, an alloy, and/or a metal oxide. In one or more embodiments, the preliminary conductive pattern CP′ may have a first thickness TH1.

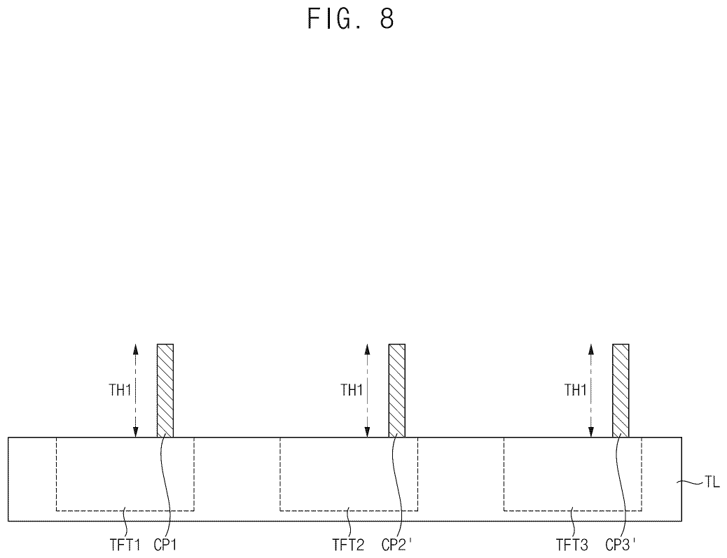

Referring to FIG. 8, a first conductive pattern CP1, a second preliminary conductive pattern CP2′, and a third preliminary conductive pattern CP3′ may be formed. In one or more embodiments, the first conductive pattern CP1, the second preliminary conductive pattern CP2′, and the third preliminary conductive pattern CP3′ may be formed together (e.g., concurrently). For example, the first conductive pattern CP1, the second preliminary conductive pattern CP2′, and the third preliminary conductive pattern CP3′ may be formed by patterning the preliminary conductive pattern CP′.

In one or more embodiments, the first conductive pattern CP1, the second preliminary conductive pattern CP2′, and the third preliminary conductive pattern CP3′ may have the same thickness. For example, the first conductive pattern CP1, the second preliminary conductive pattern CP2′, and the third preliminary conductive pattern CP3′ may have the first thickness TH1.

The first conductive pattern CP1, the second preliminary conductive pattern CP2′, and the third preliminary conductive pattern CP3′ may be connected to the first transistor TFT1, the second transistor TFT2, and the third transistor TFT3, respectively.

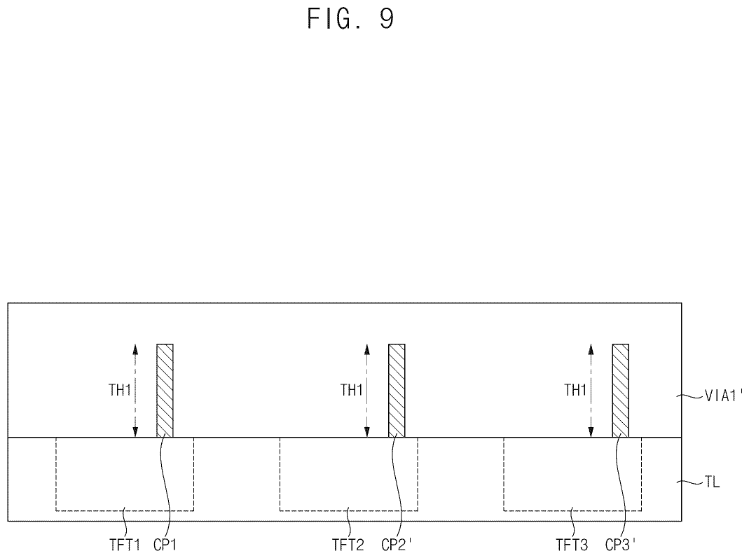

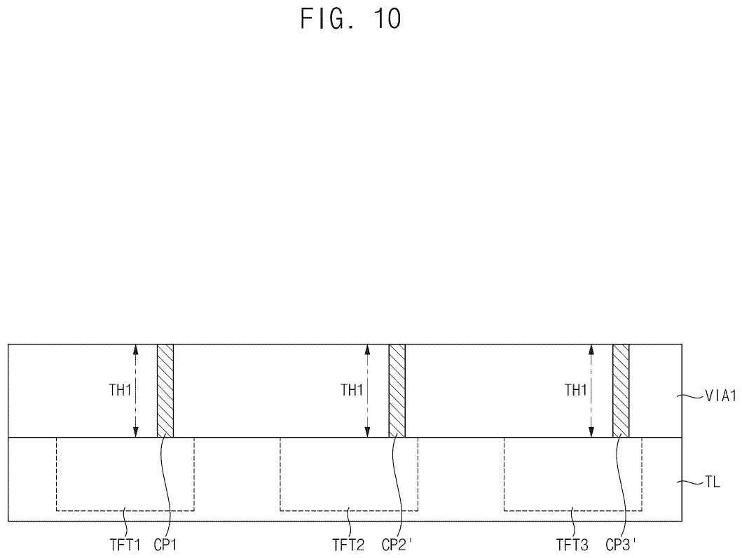

Referring to FIG. 9, a first preliminary via layer VIA1′ may be formed. In one or more embodiments, the first preliminary via layer VIA1′ may cover the first conductive pattern CP1, the second preliminary conductive pattern CP2′, and the third preliminary conductive pattern CP3′. For example, the thickness of the first preliminary via layer VIA1′ may be greater than the first thickness TH1.

Referring to FIG. 10, the first via layer VIA1 may be formed. In one or more embodiments, the first via layer VIA1 may be formed by removing a portion of the first preliminary via layer VIA1′. For example, an upper portion of the first preliminary via layer VIA1′ may be removed through a first planarization process. For example, the first planarization process may be a chemical mechanical polishing (CMP) process.

Accordingly, the upper surface of the first conductive pattern CP1 may be exposed. In addition, an upper surface of the second preliminary conductive pattern CP2′ and the upper surface of the third preliminary conductive pattern CP3′ may be exposed. For example, a thickness of the first via layer VIA1 may be substantially the same as the first thickness TH1.

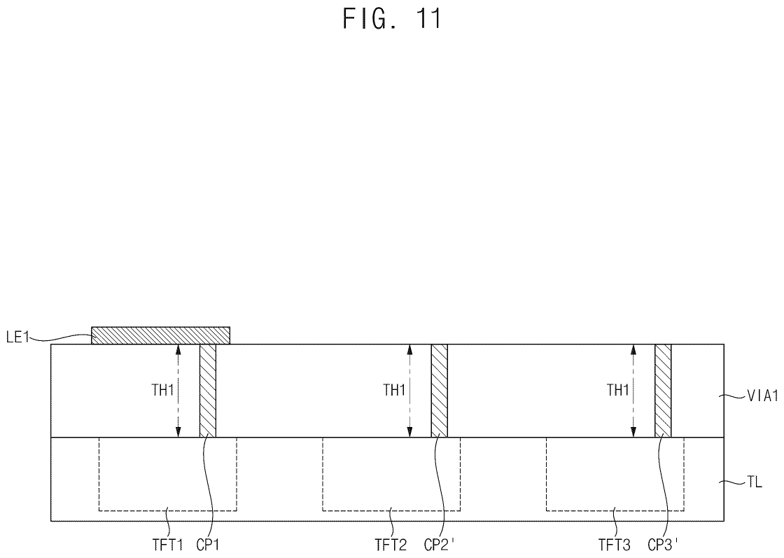

Referring to FIG. 11, a first lower electrode LE1 may be formed on the first via layer VIA1. The first lower electrode LE1 may be in contact with the first conductive pattern CP1.

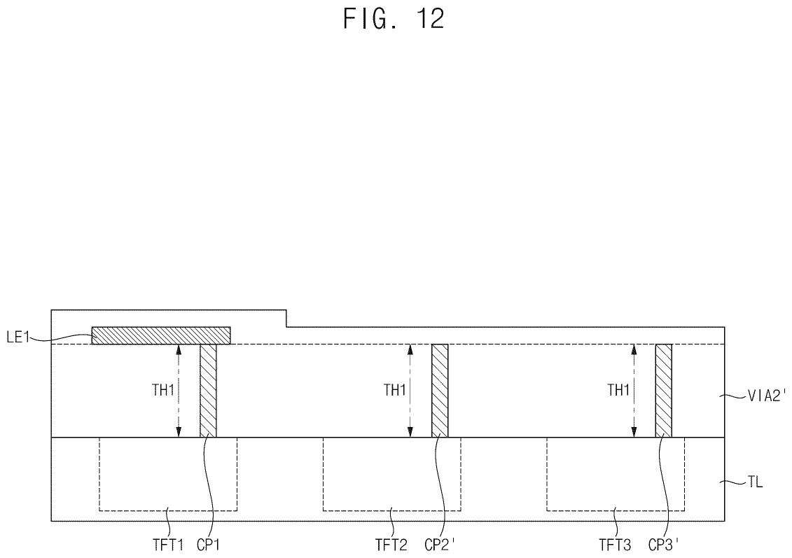

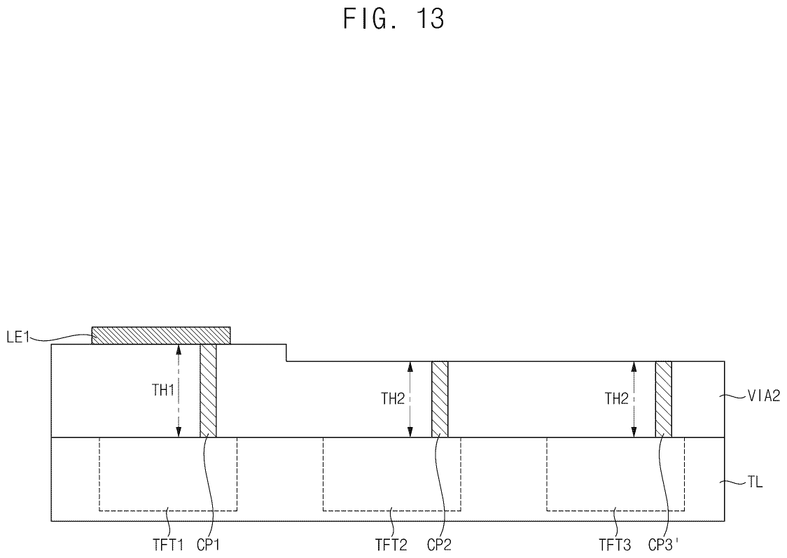

Referring to FIG. 12, a second preliminary via layer VIA2′ may be formed. In one or more embodiments, the second preliminary via layer VIA2′ may include the same material as the first via layer VIA1. In this case, the second preliminary via layer VIA2′ may be formed by further coating the material on the first via layer VIA1.

In one or more embodiments, the second preliminary via layer VIA2′ may cover the first via layer VIA1 and the first lower electrode LE1. In one or more embodiments, the second preliminary via layer VIA2′ may further cover the upper surface of the second preliminary conductive pattern CP2′ and the upper surface of the third preliminary conductive pattern CP3′.

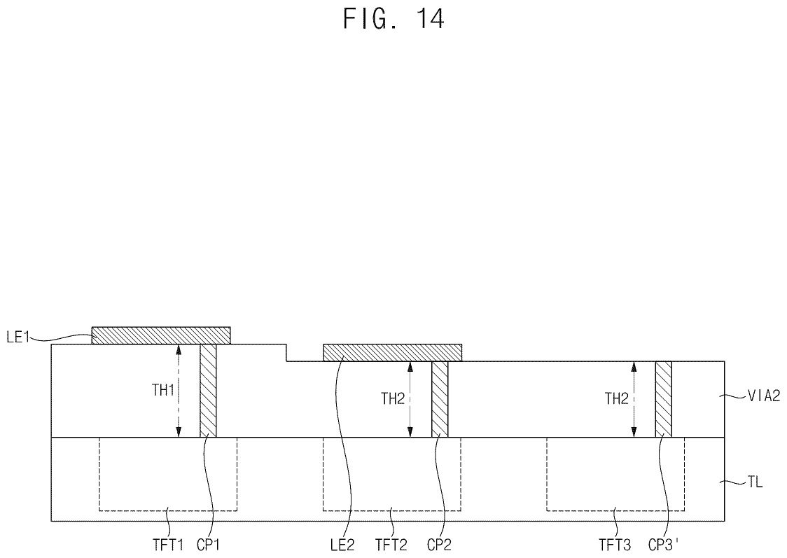

Referring to FIG. 13, a second via layer VIA2 and a second conductive pattern CP2 may be formed. In one or more embodiments, a second via layer VIA2 may be formed by removing a portion of the second preliminary via layer VIA2′. For example, the upper portion of the second preliminary via layer VIA2′ may be removed through a second planarization process. For example, the second planarization process may be the CMP process.

Additionally, during the second planarization process, a portion of the second preliminary conductive pattern CP2′ and a portion of the third preliminary conductive pattern CP3′ may be removed together. Accordingly, a second conductive pattern CP2 having a second thickness TH2 may be formed. Thus, the first thickness TH1 of the first conductive pattern CP1 may be different from the second thickness TH2 of the second conductive pattern CP2.

Referring to FIG. 14, a second lower electrode LE2 may be formed on the second via layer VIA2. The second lower electrode LE2 may be in contact with the second conductive pattern CP2.

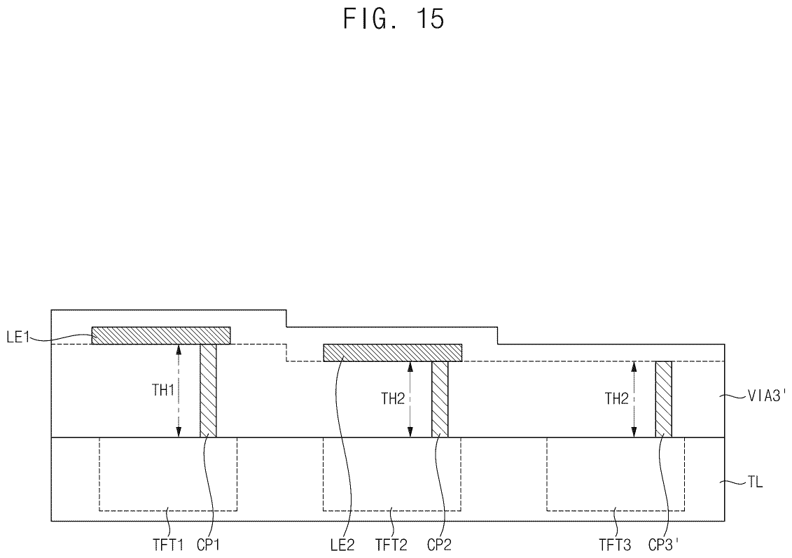

Referring to FIG. 15, a third preliminary via layer VIA3′ may be formed. In one or more embodiments, the third preliminary via layer VIA3′ may include the same material as the second via layer VIA2. In this case, the third preliminary via layer VIA3′ may be formed by further coating the material on the second via layer VIA2.

In one or more embodiments, the third preliminary via layer VIA3′ may cover the second via layer VIA2, the first lower electrode LE1, and the second lower electrode LE2. In one or more embodiments, the third preliminary via layer VIA3′ may further cover the upper surface of the third preliminary conductive pattern CP3′.

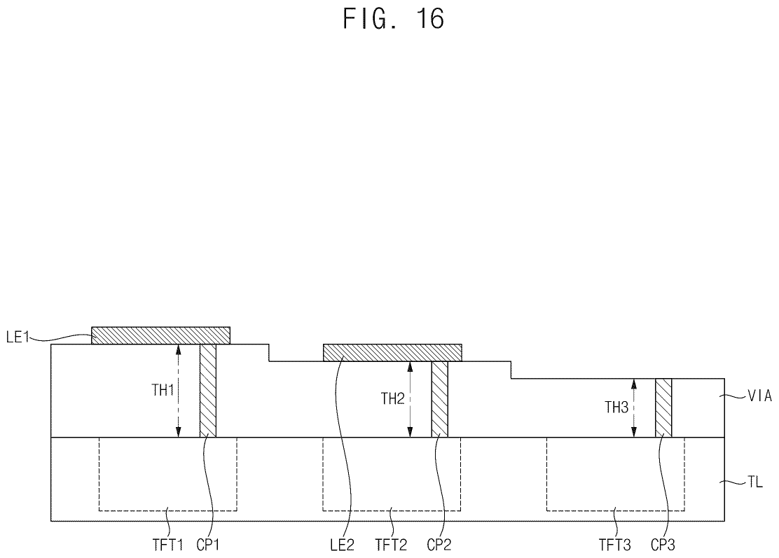

Referring to FIG. 16, a via layer VIA and a third conductive pattern CP3 may be formed. In one or more embodiments, the via layer VIA may be formed by removing a portion of the third preliminary via layer VIA3′. For example, an upper portion of the third preliminary via layer VIA3′ may be removed through a third planarization process. For example, the third planarization process may be the CMP process.

During the third planarization process, a portion of the third preliminary conductive pattern CP3′ may be removed. Accordingly, a third conductive pattern CP3 having a third thickness TH3 may be formed. Accordingly, the first thickness TH1, the second thickness TH2, and the third thickness TH3 may be different from each other.

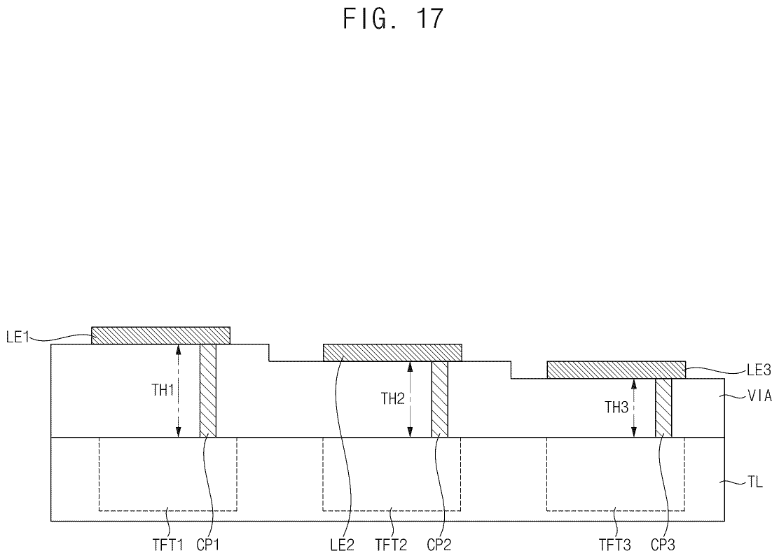

Referring to FIG. 17, a third lower electrode LE3 may be formed on the via layer VIA. The third lower electrode LE3 may be in contact with the third conductive pattern CP3.

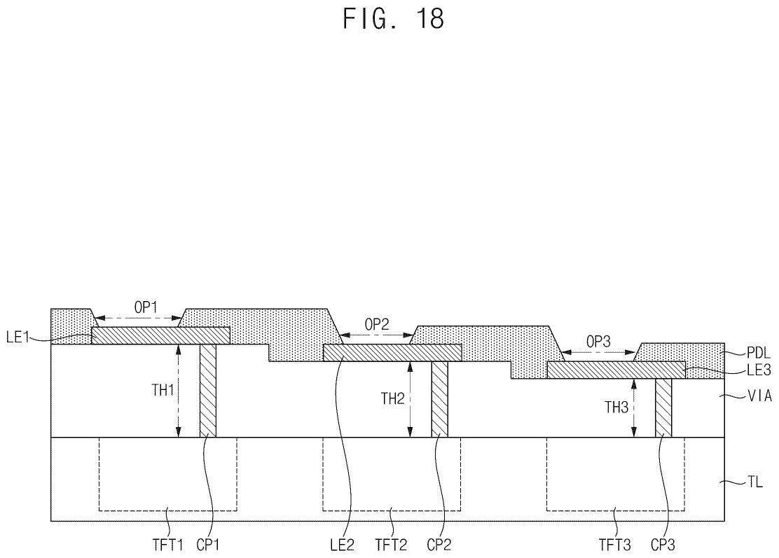

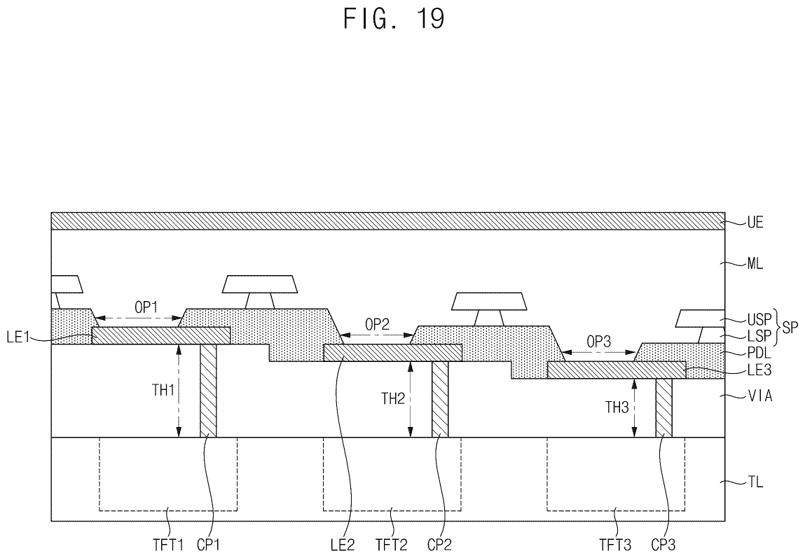

Referring to FIG. 18, a pixel defining layer PDL may be formed. The pixel defining layer PDL may cover end portions of the first lower electrode LE1, end portions of the second lower electrode LE2, and end portions of the third lower electrode LE3. In one or more embodiments, the pixel defining layer PDL may expose a portion of the first lower electrode LE1 (e.g., to define a first opening OP1), a portion of the second lower electrode LE2 (e.g., to define a second opening OP2), and a portion of the third lower electrode LE3 (e.g., to define a third opening OP3).

In one or more embodiments, the first to third conductive patterns CP1, CP2, and CP3 may overlap with the pixel defining layer PDL. In one or more embodiments, the first to third conductive patterns CP1, CP2, and CP3 may not overlap with the first to third openings OP1, OP2, and OP3.

Referring to FIG. 19, a separation layer SP, an intermediate layer ML, and an upper electrode UE may be formed sequentially. In one or more embodiments, the intermediate layer ML may be formed as a common layer, and the upper electrode UE may be formed as a common electrode.

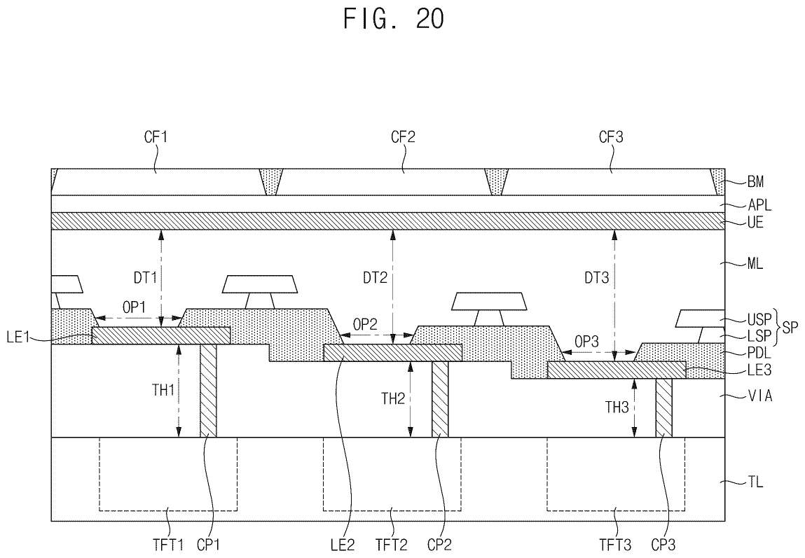

Referring to FIG. 20, a protective layer APL, a black matrix BM, a first color filter CF1, a second color filter CF2, and a third color filter CF3 may be formed. For example, the protective layer APL, the black matrix BM, the first color filter CF1, the second color filter CF2, and the third color filter CF3 may be formed sequentially.

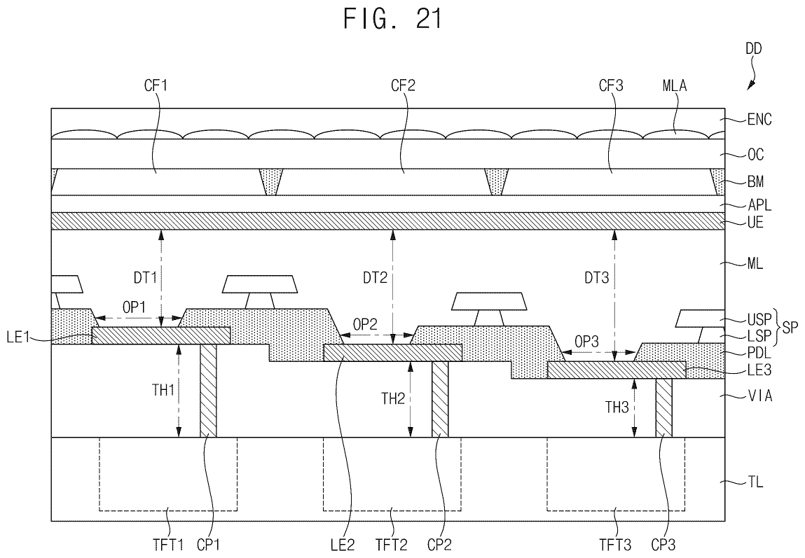

Referring to FIG. 21, a planarization layer OC, a micro lens array MLA, and an encapsulation layer ENC may be formed.

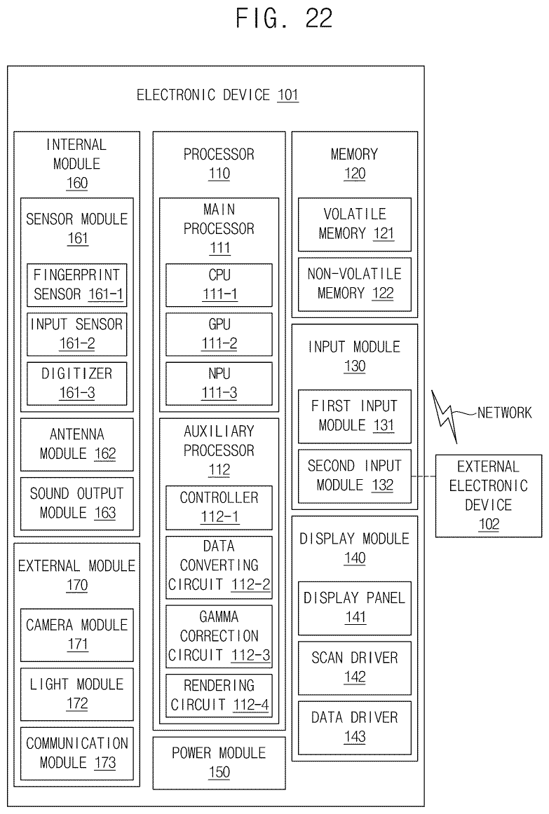

FIG. 22 is a block diagram illustrating an electronic device according to one or more embodiments.

Referring to FIG. 22, the electronic device 101 may output one or more suitable information through a display module 140 within an operating system. The display module 140 may be the display device according to the present embodiments (e.g., as described above). When a processor 110 executes an application stored in a memory 120, the display module 140 may provide application information to a user through a display panel 141.

The processor 110 may obtain an external input through an input module 130 and/or a sensor module 161 and may execute an application corresponding to the external input. For example, if (e.g., when) the user selects a camera icon displayed on the display panel 141, the processor 110 may obtain a user input through an input sensor 161-2 and may activate a camera module 171. The processor 110 may be to transmit image data corresponding to a captured image obtained through the camera module 171 to the display module 140. The display module 140 may display an image corresponding to the captured image through the display panel 141.

As another example, if (e.g., when) personal information authentication is executed in the display module 140, a fingerprint sensor 161-1 may obtain fingerprint information, which is input, as input data. The processor 110 may compare the input data obtained through the fingerprint sensor 161-1 with authentication data stored in the memory 120 and may execute an application according to a comparison result. The display module 140 may display information executed according to logic of the application through the display panel 141.

As still another example, if (e.g., when) a music-streaming icon displayed on the display module 140 is selected, the processor 110 may obtain the user input through the input sensor 161-2 and may activate a music streaming application stored in the memory 120. When a music execution command is input in the music streaming application, the processor 110 may activate a sound output module 163 to provide sound information corresponding to the music execution command to the user.

An operation of the electronic device 101 has been briefly described above. Hereinafter, a configuration of the electronic device 101 will be described in more detail. Some of components of the electronic device 101 that will be described herein below may be integrated with each other so as to be provided as one component, and one component may be separated into two or more components so as to be provided as separate components.

Referring to FIG. 22, the electronic device 101 may communicate with an external electronic device 102 through a network (e.g., a short-range wireless communication network and/or a long-range wireless communication network). In one or more embodiments, the electronic device 101 may include a processor 110, a memory 120, an input module 130, a display module 140, a power module 150, an internal module 160, and an external module 170. In one or more embodiments, at least one of the components described above may not be provided in the electronic device 101, and/or one or more other components may be added to the electronic device 101. In one or more embodiments, some of the components described above (e.g., the sensor module 161, an antenna module 162, and/or the sound output module 163) may be integrated into another component (e.g., the display module 140).

The processor 110 may execute software to control at least one of other components (e.g., hardware and/or software components) of the electronic device 101 connected to the processor 110 and may perform one or more suitable data processing and/or calculations. In one or more embodiments, as at least portion of the data processing and/or calculations, the processor 110 may store a command and/or data received from another component (e.g., the input module 130, the sensor module 161, and/or a communication module 173) in a volatile memory 121, may process the command and/or data stored in the volatile memory 121, and may store result data in a non-volatile memory 122.

The processor 110 may include a main processor 111 and an auxiliary processor 112. The main processor 111 may include at least one selected from among a central processing unit (CPU) 111-1 and an application processor (AP). The main processor 111 may further include at least one selected from among a graphic processing unit (GPU) 111-2, a communication processor (CP), and an image signal processor (ISP). The main processor 111 may further include a neural processing unit (NPU) 111-3. The neural processing unit may be a processor specialized in processing of an artificial intelligence model, and the artificial intelligence model may be generated through machine learning. The artificial intelligence model may include a plurality of artificial neural network layers. An artificial neural network may be one selected from among a deep neural network (DNN), a convolutional neural network (CNN), a recurrent neural network (RNN), a restricted Boltzmann machine (RBM), a deep belief network (DBN), a bidirectional recurrent deep neural network (BRDNN), a deep Q-network, and a combination of at least two thereof, but is not limited to the examples described above. The artificial intelligence model may additionally or alternatively include a software structure in addition to a hardware structure. At least two selected from among the processing units and processors described above may be implemented as one integrated component (e.g., a single chip), or may be implemented as independent components (e.g., a plurality of chips), respectively.

The auxiliary processor 112 may include a controller 112-1. The controller 112-1 may include an interface conversion circuit and a timing control circuit. The controller 112-1 may receive an image signal from the main processor 111 and may convert a data format of the image signal to meet interface specifications with the display module 140 to output image data. The controller 112-1 may output one or more suitable control signals desired or required for driving the display module 140.

The auxiliary processor 112 may further include a data conversion circuit 112-2, a gamma correction circuit 112-3, a rendering circuit 112-4, and/or the like. The data conversion circuit 112-2 may receive the image data from the controller 112-1 and may compensate for the image data to display an image with a desired or suitable luminance according to characteristics of the electronic device 101, settings of the user, and/or the like, and/or may convert the image data for reduction of power consumption, afterimage compensation, and/or the like. The gamma correction circuit 112-3 may convert the image data, a gamma reference voltage, and/or the like so that an image displayed on the electronic device 101 may have a desired or suitable gamma characteristic. The rendering circuit 112-4 may receive the image data from the controller 112-1 and may render the image data in consideration of a pixel arrangement and/or the like of the display panel 141 applied to the electronic device 101. At least one selected from among the data conversion circuit 112-2, the gamma correction circuit 112-3, and the rendering circuit 112-4 may be integrated into another component (e.g., the main processor 111 and/or the controller 112-1). At least one selected from among the data conversion circuit 112-2, the gamma correction circuit 112-3, and the rendering circuit 112-4 may be integrated into a data driver 143 that will be described in more detail.

The memory 120 may store one or more suitable data used by at least one of the components (e.g., the processor 110 and/or the sensor module 161) of the electronic device 101 and input data and/or output data for a command associated with the stored one or more suitable data. The memory 120 may include at least one selected from among the volatile memory 121 and the non-volatile memory 122.

The input module 130 may receive a command and/or data to be used for the components (e.g., the processor 110, the sensor module 161, and/or the sound output module 163) of the electronic device 101 from an outside of the electronic device 101 (e.g., the user and/or the external electronic device 102).

The input module 130 may include a first input module 131 configured to receive a command and/or data from the user and a second input module 132 configured to receive a command and/or data from the external electronic device 102. The first input module 131 may include a microphone, a mouse device, a keyboard, a key (e.g., a button), and/or a pen (e.g., a passive pen and/or an active pen). The second input module 132 may support a designated protocol capable of enabling wired and/or wireless connection with the external electronic device 102. In one or more embodiments, the second input module 132 may include a high-definition multimedia interface (HDMI), a universal serial bus (USB) interface, an SD card interface, and/or an audio interface. The second input module 132 may include a connector capable of enabling physical connection with the external electronic device 102, for example, an HDMI connector, a USB connector, an SD card connector, and/or an audio connector (e.g., a headphone connector).

The display module 140 may visually provide information to the user. The display module 140 may include a display panel 141, a scan driver 142, and a data driver 143. The display module 140 may further include a window, a chassis, and a bracket configured to protect the display panel 141.

The display panel 141 may include a liquid crystal display panel, an organic light emitting display panel, and/or an inorganic light emitting display panel. However, a type or kind of display panel 141 is not particularly limited thereto. The display panel 141 may be a rigid type or kind or a flexible type or kind that may be rolled and/or folded. The display module 140 may further include a supporter, a bracket, a heat dissipation member, and/or the like configured to support the display panel 141.

The scan driver 142 may be mounted on the display panel 141 as a driving chip. In one or more embodiments, the scan driver 142 may be integrated on the display panel 141. For example, the scan driver 142 may include an amorphous silicon TFT gate driver circuit (ASG), a low-temperature polycrystalline silicon (LTPS) TFT gate driver circuit, and/or an oxide semiconductor TFT gate driver circuit (OSG), which is embedded in the display panel 141. The scan driver 142 may receive a control signal from the controller 112-1 and may output scan signals to the display panel 141 in response to the control signal.

The display panel 141 may further include an emission driver. The emission driver may output an emission signal to the display panel 141 in response to the control signal received from the controller 112-1. The emission driver may be formed separately from the scan driver 142, or may be integrated into the scan driver 142.

The data driver 143 may receive the control signal from the controller 112-1, may convert the image data into an analog voltage (e.g., a data voltage) in response to the control signal, and may output data voltages to the display panel 141.

The data driver 143 may be integrated into another component (e.g., the controller 112-1). The functions of the interface conversion circuit and/or the timing control circuit of the controller 112-1 described above may be integrated into the data driver 143.

The display module 140 may further include a light emission driver, a voltage generation circuit, and/or the like. The voltage generation circuit may output one or more suitable voltages desired or required for driving the display panel 141.

The power module 150 may supply a power to the components of the electronic device 101. The power module 150 may include a battery configured to charge a power voltage. The battery may include a primary battery that is non-rechargeable, and a secondary battery and/or a fuel battery, which is rechargeable. The power module 150 may include a power management integrated circuit (PMIC). The PMIC may supply an improved or optimized power to each of the modules described above and modules that will be described in more detail herein below. The power module 150 may include a wireless power transmission/reception member electrically connected to the battery. The wireless power transmission/reception member may include a plurality of antenna radiators having a coil shape.

The electronic device 101 may further include an internal module 160 and an external module 170. The internal module 160 may include a sensor module 161, an antenna module 162, and a sound output module 163. The external module 170 may include a camera module 171, a light module 172, and a communication module 173.

The sensor module 161 may sense an input caused by a body of the user and/or an input caused by the pen among the first input module 131 and may generate an electrical signal and/or a data value corresponding to the input. The sensor module 161 may include at least one selected from among a fingerprint sensor 161-1, an input sensor 161-2, and a digitizer 161-3.

The fingerprint sensor 161-1 may generate a data value corresponding to a fingerprint of the user. The fingerprint sensor 161-1 may include one selected from among optical and capacitive fingerprint sensors.

The input sensor 161-2 may generate a data value corresponding to coordinate information of the input caused by the body of the user and/or the input caused by the pen. The input sensor 161-2 may generate a capacitance variation caused by the input as the data value. The input sensor 161-2 may sense an input caused by the passive pen and/or may be to transmit/receive data to/from the active pen.

The input sensor 161-2 may measure a bio signal such as a blood pressure, moisture, and/or body fat. For example, if (e.g., when) the user does not move for a set or predetermined time while allowing a portion of the body to make contact with a sensor layer or a sensing panel, the input sensor 161-2 may sense the bio signal to output information desired or suitable by the user to the display module 140 based on an electric field variation caused by the portion of the body.

The digitizer 161-3 may generate a data value corresponding to coordinate information of the input caused by the pen. The digitizer 161-3 may generate an electromagnetic variation caused by the input as the data value. The digitizer 161-3 may sense the input caused by the passive pen and/or may be to transmit/receive data to/from the active pen.

At least one selected from among the fingerprint sensor 161-1, the input sensor 161-2, and the digitizer 161-3 may be implemented as a sensor layer formed on the display panel 141 through consecutive processes. The fingerprint sensor 161-1, the input sensor 161-2, and the digitizer 161-3 may be provided on the display panel 141, and one selected from among the fingerprint sensor 161-1, the input sensor 161-2, and the digitizer 161-3, for example, the digitizer 161-3 may be provided under the display panel 141.

At least two selected from among the fingerprint sensor 161-1, the input sensor 161-2, and the digitizer 161-3 may be integrated into one sensing panel through substantially the same process. When integrated into one sensing panel, the sensing panel may be provided between the display panel 141 and the window on the display panel 141. In one or more embodiments, the sensing panel may be provided on the window. However, a location of the sensing panel is not particularly limited thereto.

At least one selected from among the fingerprint sensor 161-1, the input sensor 161-2, and the digitizer 161-3 may be embedded in the display panel 141. For example, at least one selected from among the fingerprint sensor 161-1, the input sensor 161-2, and the digitizer 161-3 may be concurrently (e.g., simultaneously) formed through a process of forming elements included in the display panel 141 (e.g., a light-emitting element, a transistor, and/or the like).

In one or more embodiments, the sensor module 161 may generate an electrical signal and/or a data value corresponding to an internal state and/or an external state of the electronic device 101. The sensor module 161 may further include, for example, a gesture sensor, a gyro sensor, an atmospheric pressure sensor, a magnetic sensor, an acceleration sensor, a grip sensor, a proximity sensor, a color sensor, an infrared (IR) sensor, a biosensor, a temperature sensor, a humidity sensor, and/or an illuminance sensor.

The antenna module 162 may include at least one antenna configured to transmit a signal and/or a power to the outside and/or receive the signal and/or the power from the outside. In one or more embodiments, the communication module 173 may be to transmit the signal to the external electronic device 102 and/or may receive the signal from the external electronic device 102 through an antenna suitable for a communication scheme. An antenna pattern of the antenna module 162 may be integrated into one of the components of the display module 140 (e.g., the display panel 141), the input sensor 161-2, and/or the like.

The sound output module 163 may be a device configured to output a sound signal to the outside of the electronic device 101 and may include, for example, a speaker used for general purposes such as multimedia playback and/or recording playback and a receiver used exclusively for receiving a phone call. In one or more embodiments, the receiver may be formed integrally with or separately from the speaker. A sound output pattern of the sound output module 163 may be integrated into the display module 140.

The camera module 171 may capture a still image and/or a moving image. In one or more embodiments, the camera module 171 may include at least one selected from among lens, an image sensor, and an image signal processor. The camera module 171 may further include an infrared camera capable of measuring presence or absence of the user, a location of the user, a line of sight of the user, and/or the like.

The light module 172 may provide a light. The light module 172 may include a light-emitting diode and/or a xenon lamp. The light module 172 may operate in conjunction with the camera module 171 or may operate independently.

The communication module 173 may support establishing a wired and/or wireless communication channel between the electronic device 101 and the external electronic device 102 and may support performing communication through the established communication channel. The communication module 173 may include one or both (e.g., simultaneously) selected from among a wireless communication module such as a cellular communication module, a short-range wireless communication module, and a global navigation satellite system (GNSS) communication module, and a wired communication module such as a local area network (LAN) communication module and/or a power line communication module. The communication module 173 may communicate with the external electronic device 102 through a short-range communication network such as Bluetooth, Wi-Fi direct, and/or infrared data association (IrDA), and/or a long-range communication network such as a cellular network, the Internet, and/or a computer network (e.g., LAN and/or WAN). Various types (kinds) of the communication modules 173 described above may be implemented as a single chip or may be implemented as separate chips, respectively.

The input module 130, the sensor module 161, the camera module 171, and/or the like may be used to control an operation of the display module 140 in conjunction with the processor 110.

The processor 110 may output the command and/or data to the display module 140, the sound output module 163, the camera module 171, and/or the light module 172 based on the input data received from the input module 130. For example, the processor 110 may generate the image data corresponding to the input data applied through the mouse device, the active pen, and/or the like to output the generated image data to the display module 140, and/or may generate command data corresponding to the input data to output the generated command data to the camera module 171 and/or the light module 172. The processor 110 may switch an operation mode of the electronic device 101 to a low-power mode and/or a sleep mode so as to reduce a power consumed by the electronic device 101 if (e.g., when) the input data is not received from the input module 130 for a set or predetermined time.

The processor 110 may output the command and/or data to the display module 140, the sound output module 163, the camera module 171, and/or the light module 172 based on sensing data received from the sensor module 161. For example, the processor 110 may compare authentication data applied by the fingerprint sensor 161-1 with authentication data stored in the memory 120 and may execute an application according to a comparison result. The processor 110 may execute a command and/or may output a corresponding image data to the display module 140 based on the sensing data sensed by the input sensor 161-2 and/or the digitizer 161-3. When the sensor module 161 includes a temperature sensor, the processor 110 may receive temperature data on a temperature measured by the sensor module 161 and may further perform luminance correction and/or the like on the image data based on the temperature data.

The processor 110 may receive measurement data on the presence or absence of the user, the location of the user, the line of sight of the user, and/or the like from the camera module 171. The processor 110 may further perform the luminance correction and/or the like on the image data based on the measurement data. For example, the processor 110 that has determined the presence or absence of the user through an input from the camera module 171 may output image data in which a luminance is corrected through the data conversion circuit 112-2 and/or the gamma correction circuit 112-3 to the display module 140.

Some of the components described above may be connected to each other through a communication scheme between peripheral devices, for example, a bus, general purpose input/output (GPIO), a serial peripheral interface (SPI), a mobile industry processor interface (MIPI), and/or an ultra path interconnect (UPI) link so as to exchange a signal (e.g., the command or data) with each other. The processor 110 may communicate with the display module 140 through a prescribed interface, may use, for example, one of the communication schemes described above, and is not limited to the communication schemes described above.

The electronic device 101 according to one or more embodiments disclosed in this document may be a device of one or more suitable forms. For example, the electronic device 101 may include at least one selected from among a portable communication device (e.g., a smart phone), a computing device, a portable multimedia device, a portable medical device, a camera, a wearable device, and a home appliance. However, the electronic device 101 is not limited thereto.

A person of ordinary skill in the art would appreciate, in view of the present disclosure in its entirety, would appreciate that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

Although the present disclosure has been described with reference to one or more embodiments thereof, it will be understood by those skilled in the art that one or more suitable modifications and changes may be made to the present disclosure without departing from the spirit and scope of the present disclosure as set forth in the following claims and equivalents thereof.

The present disclosure may be applied to a display device and an electronic device including the display device. For example, the present disclosure may be applied to a high-resolution smart phone, a cellular phone, a smart pad, a smart watch, a tablet PC, a vehicle navigation system, a television, a computer monitor, a laptop, and/or the like.

What is claimed is:

1. A display device comprising:
a first lower electrode on a first transistor and electrically connected to the first transistor;
a first conductive pattern between the first transistor and the first lower electrode, the first conductive pattern electrically connecting the first transistor and the first lower electrode, and having a first thickness;
a second lower electrode on a second transistor different from the first transistor, electrically connected to the second transistor, and being adjacent to the first lower electrode; and
a second conductive pattern between the second transistor and the second lower electrode, the second conductive pattern electrically connecting the second transistor and the second lower electrode, and having a second thickness different from the first thickness.

2. The display device of claim 1, wherein the first conductive pattern comprises a different material from the first lower electrode,
wherein the first conductive pattern comprises a metal oxide, and
wherein the second conductive pattern comprises the same material as the first conductive pattern.

3. The display device of claim 1, wherein a first height of the first lower electrode is different from a second height of the second lower electrode, and
wherein a difference between the first height and the second height is equal to a difference between the first thickness and the second thickness.

4. The display device of claim 1, further comprising:
a via layer between the first transistor and the first lower electrode and covering a first side surface of the first conductive pattern and a second side surface of the second conductive pattern,
wherein a portion of an upper surface of the via layer coincides with an upper surface of the first conductive pattern and another portion of the upper surface of the via layer coincides with an upper surface of the second conductive pattern.

5. The display device of claim 4, wherein the upper surface of the first conductive pattern does not coincide with the upper surface of the second conductive pattern.

6. The display device of claim 4, wherein a lower surface of the via layer, a lower surface of the first conductive pattern, and a lower surface of the second conductive pattern coincide with each other.

7. The display device of claim 4, wherein a thickness of the via layer covering the first side surface of the first conductive pattern is different from a thickness of the via layer covering the second side surface of the second conductive pattern, and
wherein the via layer comprises an organic material.

8. The display device of claim 1, further comprising:
a pixel defining layer on the first lower electrode and the second lower electrode and overlapping with the first conductive pattern and the second conductive pattern,
wherein the pixel defining layer exposes a portion of the first lower electrode to define a first opening and a portion of the second lower electrode to define a second opening,
wherein the first conductive pattern does not overlap with the first opening,
wherein the second conductive pattern does not overlap with the second opening,
wherein the pixel defining layer covers end portions of the first lower electrode and end portions of the second lower electrode,
wherein the first conductive pattern overlaps with one of the end portions of the first lower electrode, and
wherein the second conductive pattern overlaps with one of the end portions of the second lower electrode.

9. The display device of claim 1, further comprising:
an intermediate layer on the first lower electrode and being in contact with the first lower electrode; and
an upper electrode on the intermediate layer,
wherein the first conductive pattern is in contact with the first lower electrode,
wherein the intermediate layer is further in contact with the second lower electrode,
wherein a first distance from the first lower electrode to the upper electrode is different from a second distance from the second lower electrode to the upper electrode, and
wherein a difference between the first distance and the second distance is equal to a difference between the first thickness and the second thickness.

10. The display device of claim 1, further comprising:
a first color filter on the first lower electrode;
a second color filter on the second lower electrode; and
a micro lens array on the first and second color filters.

11. A display device comprising:
a first lower electrode on a first transistor and electrically connected to the first transistor;
a first conductive pattern between the first transistor and the first lower electrode, the first conductive pattern electrically connecting the first transistor and the first lower electrode; and
a via layer between the first transistor and the first lower electrode, the via layer covering a first side surface of the first conductive pattern, and having an upper surface a portion of which coincides with an upper surface of the first conductive pattern.

12. The display device of claim 11, further comprising:
a second lower electrode on a second transistor different from the first transistor, the second lower electrode being electrically connected to the second transistor, and being adjacent to the first lower electrode; and
a second conductive pattern between the second transistor and the second lower electrode, the second conductive pattern electrically connecting the second transistor and the second lower electrode, and having a thickness different from a thickness of the first lower electrode,
wherein the via layer further covers a second side surface of the second conductive pattern, and
wherein another portion of the upper surface of the via layer coincides with an upper surface of the second conductive pattern.

13. The display device of claim 12, wherein the upper surface of the first conductive pattern does not coincide with the upper surface of the second conductive pattern.

14. The display device of claim 12, wherein a lower surface of the via layer, a lower surface of the first conductive pattern, and a lower surface of the second conductive pattern coincide with each other.

15. The display device of claim 12, wherein a thickness of the via layer covering the first side surface is different from a thickness of the via layer covering the second side surface, and
wherein the via layer comprises an organic material.

16. A method of manufacturing a display device, the method comprising:
forming a first conductive pattern on a substrate, the first conductive pattern being electrically connected to a first transistor;
forming a second preliminary conductive pattern on the substrate, the second preliminary conductive pattern being connected to a second transistor different from the first transistor;
forming a first preliminary via layer covering the first conductive pattern and the second preliminary conductive pattern;
forming a first via layer that exposes an upper surface of the first conductive pattern by removing a portion of the first preliminary via layer;
forming a second preliminary via layer on the first via layer; and
forming a second via layer and a second conductive pattern by removing a portion of the second preliminary via layer and a portion of the second preliminary conductive pattern.

17. The method of claim 16, further comprising:
forming a first lower electrode on the first via layer, the first lower electrode being in contact with the first conductive pattern; and
forming a second lower electrode on the second via layer, the second lower electrode being in contact with the second conductive pattern,
wherein the second preliminary via layer further covers the first lower electrode.

18. The method of claim 16, wherein a thickness of the first conductive pattern is equal to a thickness of the second preliminary conductive pattern,
wherein the thickness of the first conductive pattern is different from a thickness of the second conductive pattern,
wherein the first via layer is formed through a first planarization process,
wherein the second via layer is formed through a second planarization process, and
wherein the first planarization process and the second planarization process are chemical mechanical polishing (CMP) processes.

19. The method of claim 16, further comprising:
forming a preliminary conductive pattern on the substrate,
wherein the first conductive pattern and the second preliminary conductive pattern are formed together,
wherein the first conductive pattern and the second preliminary conductive pattern are formed by patterning the preliminary conductive pattern, and
wherein a thickness of the preliminary conductive pattern is equal to a thickness of the first conductive pattern.

20. An electronic device comprising:
the display device of claim 1; and
a power module configured to supply power to the display device.
